(19) United States
(12) Patent Application Publication
(10) Pub. No.: US 2023/0411577 A1
(43) Pub. Date: Dec. 21, 2023

(54) DISPLAY DEVICE AND METHOD OF FABRICATING THE SAME

(71) Applicant: Samsung Display Co., LTD., Yongin-si (KR)

(72) Inventors: Ju Won YOON, Yongin-si (KR); Jung Hun NOH, Yongin-si (KR); Ki Seong SEO, Yongin-si (KR); Jae Gwang UM, Yongin-si (KR); So Yeon YOON, Yongin-si (KR); Sang Hyun LEE, Yongin-si (KR); Hyung Il JEON, Yongin-si (KR)

(21) Appl. No.: 18/114,189

(22) Filed: Feb. 24, 2023

(30) Foreign Application Priority Data
Jun. 20, 2022 (KR) 10-2022-0074784

(51) Int. Cl. H01L 33/62; H01L 33/20; H01L 25/075; H01L 25/16; H01L 27/12; H01L 33/38

(52) U.S. Cl. CPC H01L 33/62; H01L 33/20; H01L 25/0753; H01L 25/167; H01L 27/1214; H01L 33/38; H01L 2933/0066; H01L 2933/0016

(57) ABSTRACT

The display device includes a substrate, a thin-film transistor on the substrate and including a first electrode, a second electrode and a semiconductor layer, a first insulating layer on the thin-film transistor, an organic layer on the first insulating layer, at least one light-emitting element on the organic layer, a pixel electrode on the organic layer and in contact with a side surface of the at least one light-emitting element, a planarization layer on the side surface of the at least one light-emitting element and a common electrode on the at least one light-emitting element and the planarization layer.

### CROSS-REFERENCE TO RELATED APPLICATION

This application claims priority from Korean Patent Application No. 10-2022-0074784, filed on Jun. 20, 2022 in the Korean Intellectual Property Office, the entire content of which is hereby incorporated by reference.

### BACKGROUND

### 1. Field of the Disclosure

Embodiments of the present disclosure relate to a display device and a method for fabricating the same.

### 2. Description of the Related Art

As the information-oriented society evolves, demands for display devices are ever increasing. Display devices may be flat panel display devices such as liquid-crystal display devices, field emission display devices, and/or light-emitting display devices.

A light-emitting display device may be implemented as an organic light-emitting display device including organic light-emitting diodes as the light-emitting elements; an inorganic light-emitting display device including inorganic semiconductor elements as the light-emitting elements; or a micro-light-emitting diode display device including micro-light-emitting diodes as the light-emitting elements. In a micro light-emitting diode display device, a micro light-emitting element diode is brought into contact with a pixel electrode, and thus it may be desired or necessary to reduce the resistance of the pixel electrode.

### SUMMARY

Aspects of one or more embodiments of the present disclosure are directed towards a display device including a pixel electrode made of a high reflectance material and a method of fabricating a display device that requires no additional process of removing an oxide layer of a pixel electrode during the method of fabrication.

Additional aspects will be set forth in part in the description which follows and, in part, will be apparent from the description, or may be learned by practice of the presented embodiments of the disclosure.

According to one or more embodiments of the present disclosure, a display device includes a substrate, a thin-film transistor on the substrate and including a first electrode, a second electrode and a semiconductor layer, a first insulating layer on the thin-film transistor, an organic layer on the first insulating layer, at least one light-emitting element on the organic layer, a pixel electrode on the organic layer and in contact with a side surface of the at least one light-emitting element, a planarization layer on the side surface of the at least one light-emitting element and a common electrode on the at least one light-emitting element and the planarization layer.

In one or more embodiments, the light-emitting element may include a first contact electrode on the organic layer and in contact with the pixel electrode on the side surface, a device rod overlapping the first contact electrode and a second contact electrode overlapping the device rod and in contact with the common electrode.

In one or more embodiments, the first contact electrode may include a protrusion protruding outward from the device rod in a first direction, the pixel electrode is arranged along the protrusion, and the first direction is perpendicular to a stack direction of the device rod.

In one or more embodiments, the first contact electrode may further include a first sub-contact electrode and a second sub-contact electrode, the first sub-contact electrode may include a first protrusion protruding outward from the device rod in the first direction, and the second sub-contact electrode includes a second protrusion protruding outward from the device rod in the first direction, and the first direction is perpendicular to the stacking direction of the device rod.

In one or more embodiments, the second protrusion may protrude outward from the first protrusion in the first direction.

In one or more embodiments, the pixel electrode may be arranged along the first protrusion and the second protrusion.

In one or more embodiments, the device rod may include a first conductivity-type or kind semiconductor doped to a first polarity, an active layer formed on the first conductivity-type or kind semiconductor, a second conductivity-type or kind semiconductor formed on the active layer and doped to a second polarity opposite to the first polarity and an electrode material layer on the second conductivity-type or kind semiconductor.

In one or more embodiments, the at least one light-emitting element may include a passivation layer around (e.g., surrounding) side surfaces of the first conductivity-type or kind semiconductor, the active layer, the second conductivity-type or kind semiconductor and the electrode material layer.

In one or more embodiments, the first contact electrode may include a material having a high reflectance.

In one or more embodiments, the first contact electrode may have a height from 0.5 μm to 3 μm.

In one or more embodiments, the display device may include one or more pixel connection holes penetrating through the organic layer in a sub-pixel area.

In one or more embodiments, the pixel connection holes may include a first pixel connection hole and a second pixel connection hole penetrating through the organic layer in the sub-pixel area, wherein the at least one light-emitting element may include a first light-emitting element and a second light-emitting element in the sub-pixel area, and wherein at least a part of the first pixel connection hole or a part of the second pixel connection hole may overlap the first light-emitting element or the second light-emitting element.

In one or more embodiments, the pixel electrode may cover a second part of the first pixel connection hole or a second part of the second pixel connection hole that does not overlap the first light-emitting element or the second light-emitting element.

In one or more embodiments, a distance between the first pixel connection hole and the second pixel connection hole may be greater than a difference between a width of the first light-emitting element and a width of the first pixel connection hole, and may be smaller than a difference between a distance between the first light-emitting element and the second light-emitting element and a width of the first pixel connection hole.

According to one or more embodiments of the present disclosure, a display device includes a substrate, a pixel electrode and a common electrode extending in a first direction on the substrate and spaced apart from each other in a second direction and at least one light-emitting element on the substrate and in a space between the pixel electrode and the common electrode, and wherein the at least one light-emitting element includes a first contact electrode in contact with the pixel electrode on a side surface, and a second contact electrode in contact with the common electrode at one end of the at least one light-emitting element.

In one or more embodiments, the first contact electrode may include a protrusion protruding outward from the second contact electrode in the first direction, and wherein the pixel electrode may be arranged along the protrusion.

In one or more embodiments, the first contact electrode further may include a first sub-contact electrode and a second sub-contact electrode, and wherein the first sub-contact electrode may include a first protrusion protruding outward from the second contact electrode in the first direction, and the second sub-contact electrode may include a second protrusion protruding outward from the second contact electrode in the first direction.

In one or more embodiments, the second protrusion may protrude outward from the first protrusion in the first direction.

In one or more embodiments, the pixel electrode may be arranged along the first protrusion and the second protrusion.

According to one or more embodiments of the present disclosure, a method of fabricating a display device includes forming a substrate; forming a circuit layer on the substrate, bonding a light-emitting element on the circuit layer, disposing a material for forming a pixel electrode along an upper surface of the circuit layer and the light-emitting element, patterning the pixel electrode by applying a photoresist, exposing it to light, and developing it, forming a planarization layer on the pixel electrode and forming a common electrode on the planarization layer, wherein the pixel electrode is in contact with a side surface of the light-emitting element.

In one or more embodiments, the bonding of the light-emitting element on the circuit layer may include bonding the light-emitting element including a first contact electrode and a device rod by disposing it on the circuit layer, irradiating it with laser and pressing it, wherein the first contact electrode has a larger width than a width of the device rod in the first direction, and wherein the first direction is perpendicular to a stacking direction of the device rod.

According to one or more embodiments of the present disclosure, no additional process of removing an oxide layer of a pixel electrode is required during the processes. In one or more embodiments, a pixel electrode can be made of a high reflectance material.

However, the effects of the present disclosure are not limited to the aforementioned effects, and one or more suitable other effects are included in the present disclosure.

### BRIEF DESCRIPTION OF THE DRAWINGS

The above and other aspects, features and/or principles of the present disclosure will become more apparent by describing in more detail embodiments thereof with reference to the attached drawings, in which:

FIG. 1 is a perspective view of a display device according to one or more embodiments of the present disclosure.

FIGS. 2 and 3 are plan views showing a display device according to one or more embodiments of the present disclosure.

FIG. 4 is a circuit diagram showing a first sub-pixel of a display panel according to one or more embodiments of the present disclosure.

FIG. 5 is a circuit diagram showing a first sub-pixel of the display panel according to one or more embodiments of the present disclosure.

FIG. 6 is a layout diagram showing sub-pixels of the display area of the display panel according to one or more embodiments of the present disclosure.

FIG. 7 is a cross-sectional view showing an example of the display panel taken along line A-A′ of FIG. 6, according to one or more embodiments of the present disclosure FIG. 8 is a cross-sectional view showing an enlarged view of area B of FIG. 7, showing a pixel electrode, a light-emitting element, a common electrode, and a third planarization layer according to one or more embodiments of the present disclosure.

FIG. 9 is a cross-sectional view showing an enlarged view of area B of FIG. 7, showing a pixel electrode, a light-emitting element, a common electrode and a third planarization layer according to a modification of the embodiment(s) of FIG. 8, according to one or more embodiments of the present disclosure.

FIG. 10 is a cross-sectional view showing an enlarged view of area B of FIG. 7, showing a pixel electrode, a light-emitting element, a common electrode and a third planarization layer according to a modification of the embodiment(s) of FIG. 8, according to one or more embodiments of the present disclosure.

FIG. 11 is a cross-sectional view showing a modification of the embodiment(s) of FIG. 7, according to one or more embodiments of the present disclosure.

FIG. 12 is a cross-sectional view showing a pixel electrode, light-emitting elements, a common electrode, and a third planarization layer included in the first sub-pixel SPX1 of FIG. 11, according to one or more embodiments of the present disclosure.

FIGS. 13-15 are plan views showing the light-emitting elements and the pixel connection holes of FIG. 12, according to one or more embodiments of the present disclosure.

FIG. 16 is a cross-sectional view showing a pixel electrode, light-emitting elements, a common electrode, and a third planarization layer included in the first sub-pixel SPX1 of FIG. 11, according to one or more embodiments of the present disclosure.

FIG. 17 is a plan view showing the light-emitting elements and the connection electrodes of FIG. 16, according to one or more embodiments of the present disclosure.

FIG. 18 is a graph showing a relationship between the thickness of the first contact electrode CTE1 of the first light-emitting element LE1 of FIGS. 1-11 and the contact area of the pixel electrode PXE.

FIGS. 19-27 are cross-sectional views showing some of the processing steps of fabricating a display device according to one or more embodiments of the present disclosure.

FIG. 28 is a perspective view of a smart device including a display device according to one or more embodiments of the present disclosure.

FIG. 29 is a perspective view of a virtual reality (VR) device including a display device according to one or more embodiments of the present disclosure.

FIG. 30 is a perspective view of a dashboard and a center console of an automobile including display devices according to one or more embodiments of the present disclosure.

FIG. 31 is a transparent display device including a display device according to one or more embodiments of the present disclosure.

FIG. 32 is a perspective view of a display device according to one or more embodiments of the present disclosure.

FIG. 33 is a perspective view of a smart device including a display device according to the embodiment of FIG. 32.

### DETAILED DESCRIPTION OF THE EMBODIMENTS

The embodiments will now be described more fully hereinafter with reference to the accompanying drawings. The embodiments may, however, be provided in different forms and should not be construed as limiting. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described.

The same reference numbers indicate the same components throughout the present disclosure, and thus, descriptions thereof may not be repeated. In the accompanying drawings, the thickness of layers and regions may be exaggerated for clarity.

Some of the parts which are not associated with the description may not be provided in order to describe embodiments of the disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” refers to when an object portion is viewed from above, and the phrase “in a cross-sectional view” or “in a schematic cross-sectional view” refers to when a schematic cross-section taken by vertically cutting an object portion is viewed from the side. The terms “overlap” or “overlapped” means that a first object may be above or below or to a side of a second object depending on the view from which the first object is seen, and vice versa. Additionally, the term “overlap” may include layer, stack, face or facing, extending over, covering, or partly covering or any other suitable term as would be appreciated and understood by those of ordinary skill in the art. The expression “not overlap” may include meanings such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both (e.g., simultaneously) the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. In addition, it will also be understood that when an element or layer is referred to as being “between” two elements or layers, it can be the only element or layer between the two elements or layers, or one or more intervening elements or layers may also be present.

It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” and/or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” “substantially,” or “approximately” and similar terms are used as terms of approximation and not as terms of degree, and are intended to account for the inherent deviations in measured or calculated values that would be recognized by those of ordinary skill in the art. As used herein, these terms are inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

I As used herein, the term “and/or” includes any and all combinations of one or more of the associated listed items. For example, “A and/or B” may be understood to mean “A, B, or A and B.” The terms “and” and “or” may be used in the conjunctive or disjunctive sense and may be understood to be equivalent to “and/or.” Expressions such as “at least one of,” “a plurality of,” “one of,” and other prepositional phrases, when preceding a list of elements, should be understood as including the disjunctive if written as a conjunctive list and vice versa. In the specification and the claims, the phrase “at least one of” is intended to include the meaning of “at least one selected from the group of” for the purpose of its meaning and interpretation. For example, “at least one of A and B” may be understood to mean “A, B, or A and B.” In addition, the expressions “at least one of a, b, or c,” “at least one of a, b, and/or c,” “one selected from the group consisting of a, b, and c,” “at least one selected from a, b, and c,” “at least one from among a, b, and c,” “one from among a, b, and c”, “at least one of a to c” indicates only a, only b, only c, both a and b, both a and c, both b and c, all of a, b, and c, or variations thereof.

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and/or the present disclosure, and should not be interpreted in an ideal or excessively formal sense unless expressly so defined herein.

Hereinafter, embodiments of the present disclosure will be described in more detail with reference to the accompanying drawings.

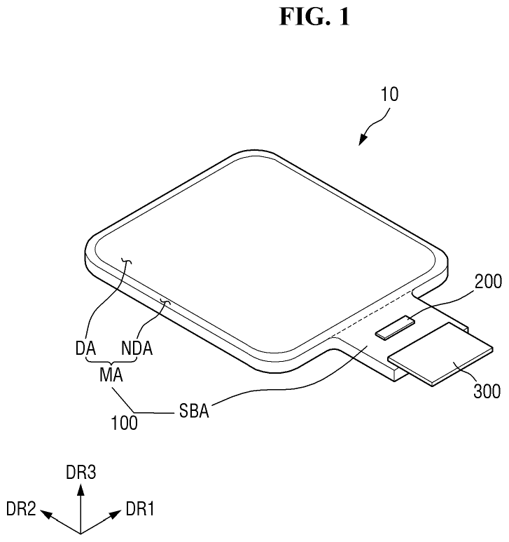

FIG. 1 is a perspective view of a display device according to one or more embodiments of the present disclosure.

Referring to FIG. 1, a display device 10 is for displaying moving images or still images. The display device 1 may be utilized as the display screen of a portable electronic device such as a mobile phone, a smart phone, a tablet PC, a smart watch, a watch phone, a mobile communications terminal, an electronic notebook, an electronic book, a portable multimedia player (PMP), a navigation device and/or an ultra-mobile PC (UMPC), as well as the display screen of one or more suitable products such as a television, a notebook, a monitor, a billboard and/or the Internet of Things.

The display device 10 may be a light-emitting display device such as an organic light-emitting display device utilizing organic light-emitting diodes, an inorganic light-emitting display device including an inorganic semiconductor, and/or a micro light-emitting display device utilizing micro or nano light-emitting diodes (micro LEDs or nano LEDs). In the following description, a micro light-emitting display device is described as an example of the display device 10. It is, however, to be understood that the present disclosure is not limited thereto. In the following description, micro or nano light-emitting diodes (micro LEDs or nano LEDs) are referred to as micro light-emitting diodes for the sake of simplicity.

The display device 10 includes a display panel 100, a display driving circuit 200 and a circuit board 300.

The display panel 100 may be formed in a rectangular plane having shorter sides in the first direction DR1 and longer sides in the second direction DR2 intersecting the first direction DR1. Each of the corners where the short side in the first direction DR1 meets the longer side in the second direction DR2 may be rounded with a set or predetermined curvature or may be a right angle. The shape of the display panel 100 when viewed from the top is not limited to a quadrangular shape, but may be formed in a different polygonal shape, a circular shape, or an elliptical shape. The display panel 100 may be formed flat, but the present disclosure is not limited thereto. For example, the display panel 100 may be formed at left and right ends, and may include a curved portion having a constant curvature or a varying curvature. In one or more embodiments, the display panel 100 may be flexible so that it can be curved, bent, folded or rolled.

A substrate SUB of the display panel 100 may include a main area MA and a subsidiary area SBA.

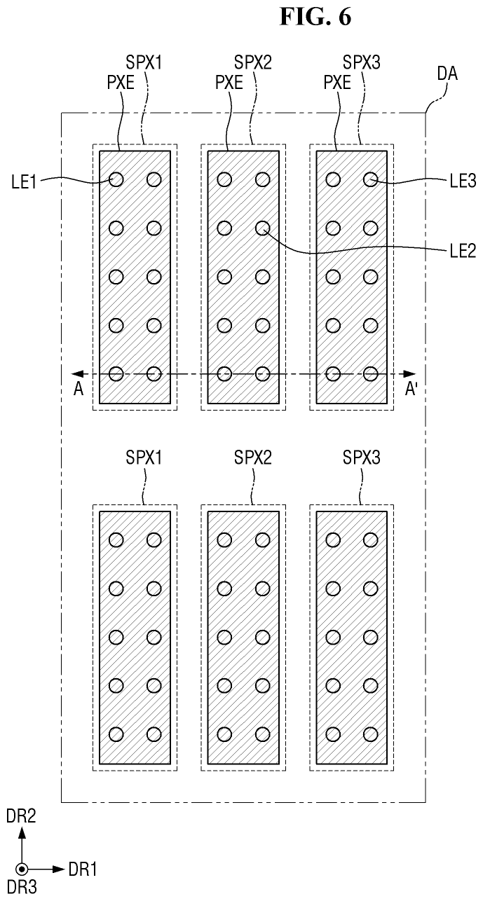

The main area MA may include a display area DA where images are displayed, and a non-display area NDA around the display area DA. The display area DA may include a plurality of sub-pixels SPX1, SPX2 and SPX3 for displaying images (see, e.g., FIG. 6). For example, the display area DA may include a first sub-pixel SPX1 for emitting a first light, a second sub-pixel SPX2 for emitting a second light, and a third sub-pixel SPX3 for emitting a third light.

The subsidiary area SBA may protrude from one side of the main area MA in the second direction DR2. Although the subsidiary area SBA is unfolded in the example shown in FIG. 1, the subsidiary area SBA may be bent and may be disposed on the lower surface of the display panel 100. When the subsidiary area SBA is bent, it may overlap the main area MA in the third direction DR3, that is the thickness direction of the display panel 100. The display driving circuit 200 may be disposed in the subsidiary area SBA.

The display driving circuit 200 may generate signals and voltages for driving the display panel 100. The display driving circuit 200 may be implemented as an integrated circuit (IC) and may be attached to the display panel 10 by a chip on glass (COG) technique, a chip on plastic (COP) technique, or an ultrasonic bonding. It is, however, to be understood that the present disclosure is not limited thereto. For example, the display driving circuit 200 may be attached on the circuit board 300 by the chip-on-film (COF) technique.

The circuit board 300 may be attached to one end of the subsidiary area SBA of the display panel 100. Accordingly, the circuit board 300 may be electrically connected to the display panel 100 and the display driving circuit 200. The display panel 100 and the display driving circuit 200 may receive digital video data, timing signals, and driving voltages through the circuit board 300. The circuit board 300 may be a flexible printed circuit board, a printed circuit board, or a flexible film such as a chip on film.

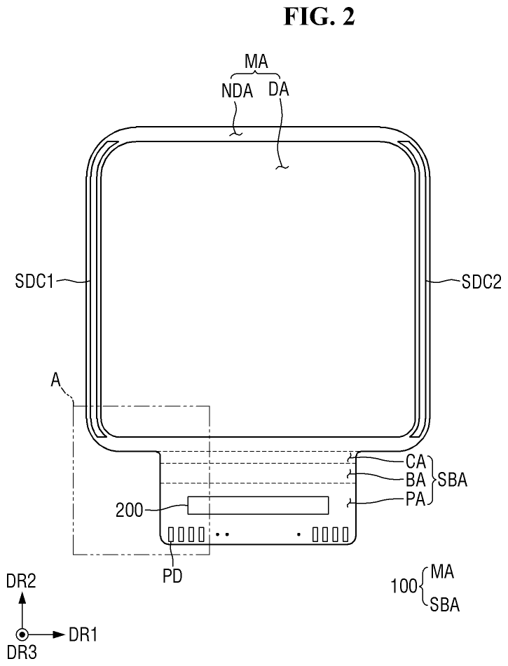

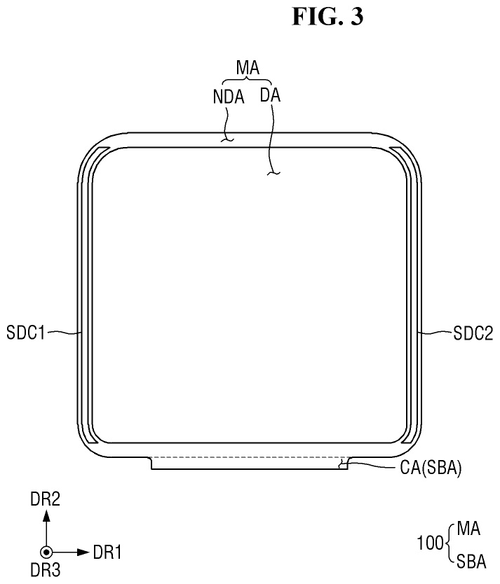

FIGS. 2 and 3 are plan views showing a display device according to one or more embodiments of the present disclosure. FIG. 2 shows the subsidiary area SBA unfolded, e.g., without being bent. FIG. 3 shows the subsidiary area SBA folded, e.g., after being bent.

Referring to FIGS. 2 and 3, the display panel 100 may include the main area MA and the subsidiary area SBA.

The main area MA may include a display area DA where images are displayed, and a non-display area NDA around the display area DA. The display area DA may occupy most of the main area MA. The display area DA may be disposed at the center of the main area MA.

The non-display area NDA may be disposed adjacent to the display area DA. The non-display area NDA may be disposed on the outer side of the display area DA. The non-display area NDA may surround the display area DA. The non-display area NDA may be defined as the border of the display panel 100.

A first scan driver SDC1 and a second scan driver SDC2 may be disposed in the non-display area NDA. The first scan driver SDC1 may be disposed on one side (e.g., the left side) of the display panel 100, and the second scan driver SDC2 may be disposed on the opposite side (e.g., the right side) of the display panel 100. It should be understood, however, that the present disclosure is not limited thereto. Each of the first scan driver SDC1 and the second scan driver SDC2 may be electrically connected to the display driving circuit 200 through scan fan-out lines. Each of the first scan driver SDC1 and the second scan driver SDC2 may receive a scan control signal from the display driving circuit 200, and may generate scan signals in response to a scan control signal to output the scan signals to scan lines.

The subsidiary area SBA may protrude from one side of the main area MA in the second direction DR2. The length of the subsidiary area SBA in the second direction DR2 may be smaller than the length of the main area MA in the second direction DR2. The length of the subsidiary area SBA in the first direction DR1 may be substantially less than the length of the main area MA in the first direction DR1 or may be substantially equal to it. The sub-area SBA may be bent and may be disposed under the display panel 100. In this instance, the subsidiary area SBA may overlap with the main area MA in the third direction DR3.

The subsidiary area SBA may include a connection electrode area CA, a pad area PA, and a bending area BA.

The connection area CA protrudes from one side of the main area MA in the second direction DR2. One side of the connection area CA may be in contact with the non-display area NDA of the main area MA, and the opposite side of the connection area CA may be in contact with the bending area BA.

In the pad area PA, pads DP and the display driving circuit 200 are disposed. The display driving circuit 200 may be attached to driving pads of the pad area PA utilizing a conductive adhesive member such as an anisotropic conductive film. The circuit board 300 may be attached to the pads DP of the pad area PA utilizing conductive adhesive members such as anisotropic conductive films. One side of the pad area PA may be in contact with the bending area BA.

The bending area BA is a part of the display panel 100 that is bendable. When the bending area BA is bent, the pad area PA may be disposed under the connection area CA and under the main area MA. The bending area BA may be disposed between the connection area CA and the pad area PA. One side of the bending area BA may be in contact with the connection area CA, and the opposite side of the bending area BA may be in contact with the pad area PA.

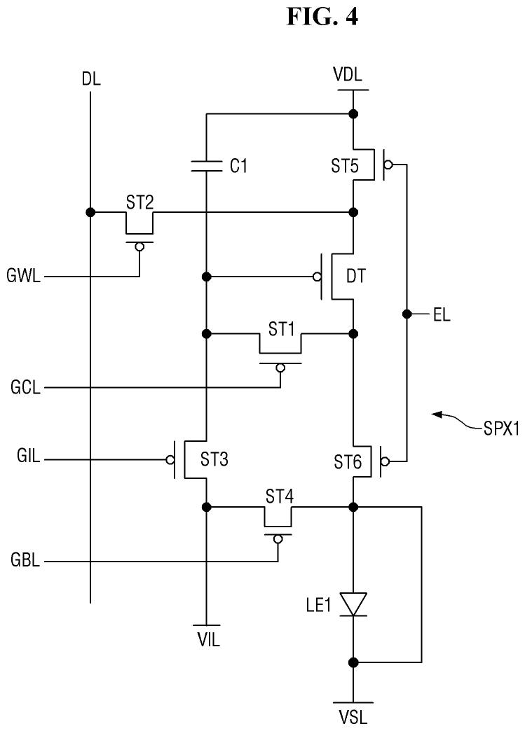

FIG. 4 is a circuit diagram showing a first sub-pixel of the display panel according to one or more embodiments of the present disclosure.

Referring to FIG. 4, a first sub-pixel SPX1 according to one or more embodiments may be connected to scan lines GWL, GIL, GCL and GBL, an emission line EL, and a data line DL. For example, the first sub-pixel SPX1 may be connected to a write scan line GWL, an initialization scan line GIL, a control scan line GCL, a bias scan line GBL, an emission line EL, and a data line DL.

According to one or more embodiments of the present disclosure, the first sub-pixel SPX1 includes a driving transistor DT, switch elements, a capacitor C1, and a first light-emitting element LE1. The switch elements include first to sixth transistors ST1, ST2, ST3, ST4, ST5 and ST6.

The driving transistor DT includes a gate electrode, a first electrode, and a second electrode. A drain-source current Ids (hereinafter referred to as “driving current”) of driving transistor DT flowing between the first electrode and the second electrode is controlled or selected according to the data voltage applied to the gate electrode.

The first light-emitting element LE1 may be an organic light-emitting diode including an anode electrode (or a pixel electrode), a cathode electrode (or a common electrode), and an organic emissive layer disposed between the anode electrode and the cathode electrode. In one or more embodiments, the first light-emitting element LE1 may be an inorganic light-emitting element including an anode electrode, a cathode electrode, and an inorganic semiconductor disposed between the anode electrode and the cathode electrode. In one or more embodiments, the first light-emitting element LE1 may be an quantum-dot light-emitting element including an anode electrode, a cathode electrode, and a quantum-dot emissive layer disposed between the anode electrode and the cathode electrode. In one or more embodiments, the first light-emitting element LE1 may be a micro light-emitting diode. In the following description, the light-emitting elements LE are micro light-emitting diodes for convenience of illustration.

The first light-emitting element LE1 emits light as the driving current Ids flows therein. The amount of the light emitted from the first light-emitting element LE1 may be proportional to the driving current Ids. The anode electrode of the first light-emitting element LE1 may be connected to the first electrode of the fourth transistor ST4 and the second electrode of the sixth transistor ST6, while the cathode electrode thereof may be connected to a second supply voltage line VSL from which a second supply voltage is applied.

The capacitor C1 is formed between the second electrode of the driving transistor DT and a first supply voltage line VDL from which a first supply voltage is applied. The first supply voltage may have a level higher than the level of the second supply voltage. One electrode of the capacitor C1 may be connected to the second electrode of the driving transistor DT while the other electrode thereof may be connected to the first voltage supply line VDL.

As shown in FIG. 4, the first to sixth transistors ST1, ST2, ST3, ST4, ST5 and ST6, and the driving transistor DT may be implemented as p-type or kind MOSFETs. In this instance, an active layer of each of the first to sixth transistors ST1, ST2, ST3, ST4, ST5 and ST6 and the driving transistor DT may be made of polysilicon or an oxide semiconductor.

The gate electrode of the second transistor ST2 may be connected to the write scan line GWL, and the gate electrode of the first transistor ST1 may be connected to the control scan line GCL. The gate electrode of the third transistor ST3 may be connected to the initialization scan line GIL, and the gate electrode of the fourth transistor ST4 may be connected to the bias scan line GBL. Because the first to sixth transistors ST1, ST2, ST3, ST4, ST5 and ST6 are implemented as p-type or kind MOSFETs, they may be turned on when the scan signal and the emission signal of a gate-low voltage are applied to the control scan line GCL, the initialization scan line GIL, the write scan line GWL, the bias scan line GBL and the emission line EL. One electrode of the third transistor ST3 and one electrode of the fourth transistor ST4 may be connected to the initialization voltage line VIL.

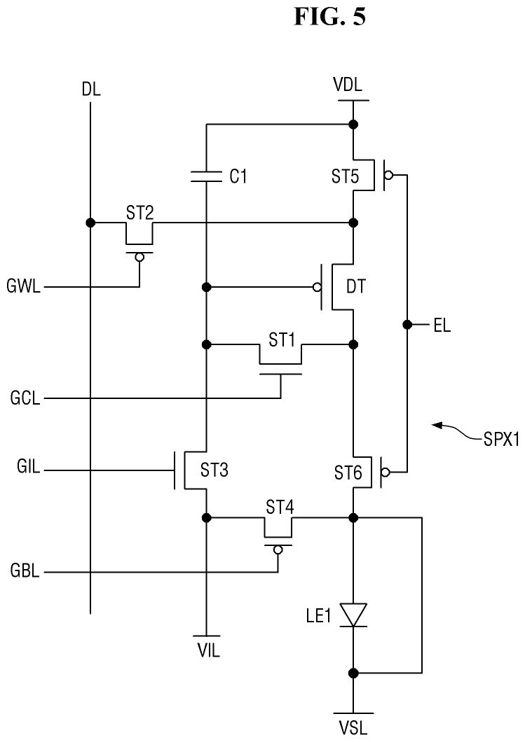

FIG. 5 is a circuit diagram showing a first sub-pixel of the display panel according to one or more embodiments of the present disclosure.

Referring to FIG. 5, the driving transistor DT, the second transistor ST2, the fourth transistor ST4, the fifth transistor ST5 and the sixth transistor ST6 may be implemented as p-type or kind MOSFETs while the first transistor ST1 and the third transistor ST3 may be implemented as n-type or kind MOSFETs. The active layer of each of the driving transistor DT, the second transistor ST2, the fourth transistor ST4, the fifth transistor ST5 and the sixth transistor ST6 implemented as p-type or kind MOSFETs may be made of polysilicon, and the active layer of the first transistor ST1 and the third transistor ST3 implemented as n-type or kind MOSFETs may be made of an oxide semiconductor. In such cases, transistors formed of polysilicon and transistors formed of an oxide semiconductor may be disposed on different layers.

Because the first transistor ST1 and the third transistor ST3 are implemented as n-type or kind (e.g., n-channel) MOSFETs, the first transistor ST1 may be turned on when a control scan signal of a gate-high voltage is applied to the control scan line GCL, and the third transistor ST3 may be turned on when an initialization scan signal is applied to the initialization scan line GIL. On the other hand, because the second transistor ST2, the fourth transistor ST4, the fifth transistor ST5 and the sixth transistor ST6 are implemented as p-type or kind (e.g., p-channel) MOSFETs, they may be turned on when a scan signal and an emission signal of the gate-low voltage are applied to the write scan line GWL, the bias scan line GBL and the emission line EL.

In one or more embodiments, in the example shown in FIG. 4, the fourth transistor ST4 may be implemented as an n-type or kind MOSFET. In this instance, the active layer of each fourth transistor ST4 may be formed of an oxide semiconductor. When the fourth transistor ST4 is implemented as an n-type or kind MOSFET, it may be turned on when a bias scan signal of the gate-high voltage is applied to the bias scan line GBL.

In one or more embodiments, although not shown in FIGS. 4 and 5, the first to sixth transistors ST1, ST2, ST3, ST4, ST5 and ST6, and the driving transistor DT all may be implemented as n-type or kind MOSFETs.

The circuit diagram of the second sub-pixel SPX2 (see, e.g., FIG. 6) and the circuit diagram of the third sub-pixel SPX3 (see, e.g., FIG. 6) according to one or more embodiments are substantially identical to the circuit diagram of the first sub-pixel SPX1 described above in conjunction with FIGS. 4 and 5; and, therefore, the redundant descriptions may not be provided.

FIG. 6 is a layout diagram showing sub-pixels of the display area of the display panel according to one or more embodiments of the present disclosure.

Referring to FIG. 6, the display area DA may include a plurality of pixels PX. Each of the pixels PX may include a first sub-pixel SPX1, a second sub-pixel SPX2 and a third sub-pixel SPX3.

The first sub-pixel SPX1 may include a pixel electrode PXE and first light-emitting elements LE1 for emitting the first light. The first light may be light in a red wavelength range. The red wavelength range may be approximately (about) 600 nm to (about) 750 nm, but the present disclosure is not limited thereto.

The second sub-pixel SPX2 may include a pixel electrode PXE and second light-emitting elements LE2 for emitting the second light. The second light may be light in a green wavelength range. The green wavelength range may be approximately (about) 480 nm to (about) 560 nm, but the present disclosure is not limited thereto.

The third sub-pixel SPX3 may include a pixel electrode PXE and third light-emitting elements LE3 for emitting the third light. The third light may be light in a blue wavelength range. The blue wavelength range may be approximately (about) 370 nm to (about) 460 nm, but the present disclosure are not limited thereto.

In each of the pixels PX, the first sub-pixel SPX1, the second sub-pixel SPX2 and the third sub-pixel SPX3 may be arranged in the first direction DR1. In one or more embodiments, the first sub-pixels SPX1 may be arranged in the second direction DR2, the second sub-pixels SPX2 may be arranged in the second direction DR2, and the third sub-pixels SPX3 may be arranged in the second direction DR2.

Although the pixel electrode PXE has a rectangular shape when viewed from the top in the example shown, the present disclosure is not limited thereto

The first light-emitting elements LE1 may be arranged in the first direction DR1 and the second direction DR2 in the first sub-pixel SPX1. For example, the first light-emitting elements LE1 may be arranged in five rows and two columns in a matrix. That is to say, ten first light-emitting elements LE1 may be disposed in the first sub-pixel SPX1.

The second light-emitting elements LE2 may be arranged in the first direction DR1 and the second direction DR2 in the second sub-pixel SPX2. For example, the second light-emitting elements LE2 may be arranged in five rows and two columns in a matrix. That is to say, ten second light-emitting elements LE2 may be disposed in the second sub-pixel SPX2.

The third light-emitting elements LE3 may be arranged in the first direction DR1 and the second direction DR2 in the third sub-pixel SPX3. For example, the third light-emitting elements LE3 may be arranged in five rows and two columns in a matrix. That is to say, ten third light-emitting elements LE3 may be disposed in the third sub-pixel SPX3.

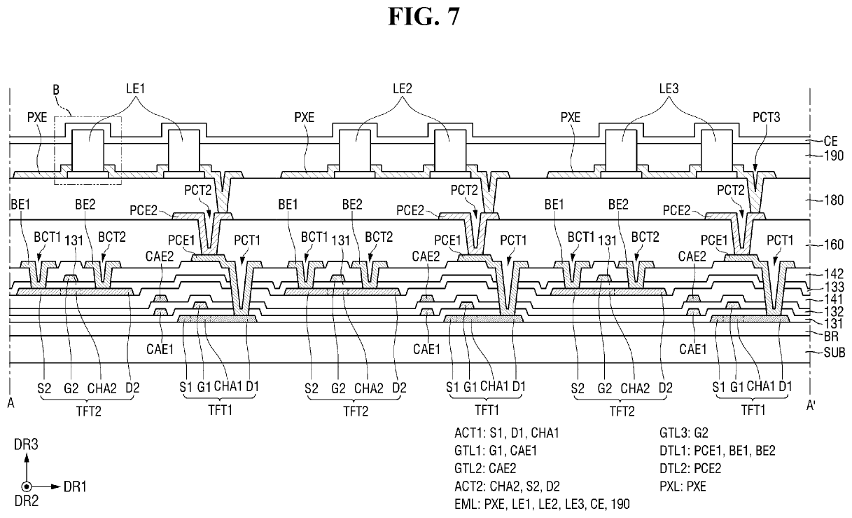

FIG. 7 is a cross-sectional view showing an example of the display panel taken along line A-A′ of FIG. 6, according to one or more embodiments of the present disclosure.

Referring to FIG. 7, a barrier layer BR may be disposed on the substrate SUB. The substrate SUB may be made of an insulating material such as a polymer resin. For example, the substrate SUB may be made of polyimide. The substrate SUB may be a flexible substrate that can be bent, folded, or rolled.

The barrier layer BR is a film for protecting the thin-film transistors of the thin-film transistor layer TFTL and an emissive layer 172 of an emission material layer EML. The barrier layer BR may be formed of multiple inorganic layers stacked on one another alternately. For example, the barrier layer BR may be made up of multiple layers in which one or more inorganic layers of a silicon nitride layer, a silicon oxynitride layer, a silicon oxide layer, a titanium oxide layer and an aluminum oxide layer are alternately stacked on one another.

A first thin-film transistor TFT1 may be disposed on the barrier layer BR. The first thin-film transistor TFT1 may be one of the fourth transistor ST4 and/or the sixth transistor ST6 shown in FIG. 5. The first thin-film transistor TFT1 may include a first active layer ACT1 and a first gate electrode G1.

A first active layer ACT1 of the first thin-film transistor TFT1 may be disposed on the barrier layer BR. The first active layer ACT1 of the first thin-film transistor TFT1 may include polycrystalline silicon, monocrystalline silicon, low-temperature polycrystalline silicon, or amorphous silicon.

The first active layer ACT1 may include a first channel region CHA1, a first source region S1 and a first drain region D1. The first channel region CHA1 may overlap with the first gate electrode G1 in the third direction DR3 that is the thickness direction of the substrate SUB. The first source region S1 may be disposed on one side of the first channel region CHA1, and the first drain region D1 may be disposed on the opposite side of the first channel region CHA1. The first source region S1 and the first drain region D1 may not overlap with the first gate electrode G1 in the third direction DR3. The first source region S1 and the first drain region D1 may have conductivity by doping a silicon semiconductor or an oxide semiconductor with ions.

A first gate insulator 131 may be disposed on the first active layer ACT1 of the first thin-film transistor TFT1. The first gate insulator 131 may be formed of an inorganic layer, for example, a silicon nitride layer, a silicon oxynitride layer, a silicon oxide layer, a titanium oxide layer, or an aluminum oxide layer.

A first gate metal layer GTL1 may be disposed on the first gate insulator 131. The first gate metal layer GTL1 may include a first gate electrode G1 of the first thin-film transistor TFT1 and a first capacitor electrode CAE1. The first gate electrode G1 may overlap the first active layer ACT1 in the third direction DR3. Although the first gate electrode G1 and the first capacitor electrode CAE1 are spaced apart from each other in the example shown in FIG. 7, the first gate electrode G1 and the first capacitor electrode CAE1 may be connected with each other. The first gate metal layer GTL1 may be made up of a single layer or multiple layers of one or more of molybdenum (Mo), aluminum (Al), chromium (Cr), gold (Au), titanium (Ti), nickel (Ni), neodymium (Nd) and/or copper (Cu) or an alloy thereof.

A second gate insulator 132 may be disposed on the first gate electrode G1 of the first thin-film transistor TFT1 and the first capacitor electrode CAE1. The second gate insulator 132 may be formed of an inorganic layer, for example, a silicon nitride layer, a silicon oxynitride layer, a silicon oxide layer, a titanium oxide layer, or an aluminum oxide layer.

A second gate metal layer GTL2 may be disposed on the second gate insulator 132. The second gate metal layer GTL2 may include a second capacitor electrode CAE2. The second capacitor electrode CAE2 may overlap the first capacitor electrode CAE1 of the first thin-film transistor TFT1 in the third direction DR3. Because the second gate insulator 132 has a certain dielectric constant, a capacitor C1 (see, e.g., FIG. 5) can be formed by the first capacitor electrode CAE1, the second capacitor electrode CAE2 and the second gate insulator 132 disposed therebetween. The second gate metal layer GTL2 may be made up of a single layer or multiple layers of one or more of molybdenum (Mo), aluminum (Al), chromium (Cr), gold (Au), titanium (Ti), nickel (Ni), neodymium (Nd) and/or copper (Cu) or an alloy thereof.

A first interlayer dielectric layer 141 may be disposed over the second capacitor electrode CAE2. The first interlayer dielectric layer 141 may be formed of an inorganic layer, for example, a silicon nitride layer, a silicon oxynitride layer, a silicon oxide layer, a titanium oxide layer, or an aluminum oxide layer.

A second thin-film transistor TFT2 may be disposed on the first interlayer dielectric layer 141. The second thin-film transistor TFT2 may be one of the first transistor ST1 and/or the third transistor ST3 shown in, e.g., FIG. 5. The second thin-film transistor TFT2 may include a second active layer ACT2 and a second gate electrode G2.

The second active layer ACT2 of the second thin-film transistor TFT2 may be disposed on the first interlayer dielectric layer 141. The second active layer ACT2 may include an oxide semiconductor. For example, the second active layer ACT2 may include IGZO (Indium (In), Gallium (Ga), Zinc (Zn) and Oxygen (O)), IGZTO (Indium (In), Gallium (Ga), Zinc (Zn), Tin (Sn) and Oxygen (O)) or IGTO (indium (In), gallium (Ga), tin (Sn) and oxygen (O)).

The second active layer ACT2 may include a second channel region CHA2, a second source region S2 and a second drain region D2. The second channel region CHA2 may overlap with the second gate electrode G2 in the third direction DR3. The second source region S2 may be disposed on one side of the second channel region CHA2, and the second drain region D2 may be disposed on the other side of the second channel region CHA2. The second source region S2 and the second drain region D2 may not overlap with the second gate electrode G2 in the third direction DR3. The second source region S2 and the second drain region D2 may have conductivity by doping an oxide semiconductor with ions.

A third gate insulator 133 may be disposed on the second active layer ACT2 of the second thin-film transistor TFT2. The third gate insulator 133 may be formed of an inorganic layer, for example, a silicon nitride layer, a silicon oxynitride layer, a silicon oxide layer, a titanium oxide layer, or an aluminum oxide layer.

A third gate metal layer GTL3 may be disposed on the third gate insulator 133. The third gate metal layer GTL3 may include the second gate electrode G2 of the second thin-film transistor TFT2. The second gate electrode G2 may overlap the second active layer ACT2 in the third direction DR3. The third gate metal layer GTL3 may be made up of a single layer or multiple layers of one or more of molybdenum (Mo), aluminum (Al), chromium (Cr), gold (Au), titanium (Ti), nickel (Ni), neodymium (Nd) and/or copper (Cu) or an alloy thereof.

A second interlayer dielectric layer 142 may be disposed on the second gate electrode G2 of the second thin-film transistor TFT2. The second interlayer dielectric layer 142 may be formed of an inorganic layer, for example, a silicon nitride layer, a silicon oxynitride layer, a silicon oxide layer, a titanium oxide layer, or an aluminum oxide layer.

A first data metal layer DTL1 may be disposed on the second interlayer dielectric layer 142. The first data metal layer DTL1 may include a first pixel connection electrode PCE1, a first bridge electrode BE10 and a second bridge electrode BE2. The first pixel connection electrode PCE1 may be connected to the first drain region D1 of the first active layer ACT1 through the first pixel connection hole PCT1 penetrating through the first gate insulator 131, the second gate insulator 132, the first interlayer dielectric layer 141, a third gate insulator 133, and the second interlayer dielectric layer 142. The first bridge electrode BE1 may be connected to the second source region S2 of the second active layer ACT2 through a first connection contact hole BCT1 penetrating through the third insulator 133 and the second interlayer dielectric layer 142. The second bridge electrode BE2 may be connected to the second drain region D2 of the second active layer ACT2 through a second connection contact hole BCT2 penetrating through the third insulator 133 and the second interlayer dielectric layer 142. The first data metal layer DTL1 may be made up of a single layer or multiple layers of one or more of molybdenum (Mo), aluminum (Al), chromium (Cr), gold (Au), titanium (Ti), nickel (Ni), neodymium (Nd) and/or copper (Cu) or an alloy thereof. For example, the first data metal layer DTL1 may include a first layer made of titanium (Ti), a second layer made of aluminum (Al), and a third layer made of titanium (Ti).

A first organic layer 160 may be disposed on the first pixel connection electrode PCE1, the first bridge electrode BE1 and the second bridge electrode BE2, in order to provide a flat surface over the first thin-film transistor TFT1 and the second thin-film transistor TFT2 having different heights. The first organic layer 160 may be formed as an organic layer such as an acryl resin, an epoxy resin, a phenolic resin, a polyamide resin and/or a polyimide resin.

A second data metal layer DTL2 may be disposed on the first organic layer 160. The second data metal layer DTL2 may include a second pixel connection electrode PCE2. The second pixel connection electrode PCE2 may be connected to the first pixel connection electrode PCE1 through a second pixel connection hole PCT2 penetrating through the first organic layer 160. The second data metal layer DTL2 may be made up of a single layer or multiple layers of one or more of molybdenum (Mo), aluminum (Al), chromium (Cr), gold (Au), titanium (Ti), nickel (Ni), neodymium (Nd) and/or copper (Cu) or an alloy thereof. For example, the second data metal layer DTL2 may include a first layer made of titanium (Ti), a second layer made of aluminum (Al), and a third layer made of titanium (Ti).

A second organic layer 180 may be disposed on the second pixel connection electrode PCE2. The second organic layer 180 may be formed as an organic layer such as an acryl resin, an epoxy resin, a phenolic resin, a polyamide resin and/or a polyimide resin.

An emission material layer EML may be disposed on the second organic layer 180. The emission material layer EML may include pixel electrodes PXE, light-emitting elements LE1, LE2 and LE3, a common electrode CE, and a planarization layer 190.

A pixel electrode layer PXL may be disposed on the second organic layer 180. The pixel electrode layer PXL may include pixel electrodes PXE. Each of the pixel electrodes PXE may be connected to the second pixel connection electrode PCE2 through a third pixel connection hole PCT3 penetrating through the second organic layer 180. Accordingly, each of the pixel electrodes PXE may be connected to the first drain region D1 (or the first source region S1) of the thin-film transistor TFT through the first pixel connection electrode PCE1 and the second pixel connection electrode PCE2. Therefore, a pixel voltage or an anode voltage controlled or selected by the thin-film transistor TFT may be applied to the pixel electrode PXE.

The pixel electrode layer PXL may be made up of a single layer or multiple layers of one or more of molybdenum (Mo), chromium (Cr), gold (Au), titanium (Ti), nickel (Ni), neodymium (Nd) and/or copper (Cu) or an alloy thereof. According to one or more embodiments of the present disclosure, the pixel electrode layer PXL may be made of a material having a higher reflectance than copper (Cu), e.g., aluminum (Al) or silver (Ag).

The first light-emitting element LE1, the second light-emitting element LE2 and the third light-emitting element LE3 may be disposed on the second organic layer 180. A vertical micro-LED extended in the third direction DR3 may be employed as an example of each of the first light-emitting element LE1, the second light-emitting element LE2 and the third light-emitting element LE3.

Each of the first light-emitting element LE1, the second light-emitting element LE2 and the third light-emitting element LE3 may be made of an inorganic material such as GaN. Each of the first light-emitting element LE1, the second light-emitting element LE2 and the third light-emitting element LE3 has a length in the first direction DR1, a length in the second direction DR2 and a length in the third direction DR3 in a range of several to several hundred μm. For example, each of the first light-emitting element LE1, the second light-emitting element LE2 and the third light-emitting element LE3 may have a length in the first direction DR1, a length in the second direction DR2 and a length in the third direction DR3 which are equal to or less than approximately (about) 100 μm.

Each of the first light-emitting element LE1, the second light-emitting element LE2 and the third light-emitting element LE3 may be grown on a semiconductor substrate such as a silicon wafer. Each of the first light-emitting element LE1, the second light-emitting element LE2 and the third light-emitting element LE3 may be transferred from the silicon wafer directly onto the second organic layer 180 of the substrate SUB. In one or more embodiments, each of the first light-emitting element LE1, the second light-emitting element LE2 and the third light-emitting element LE3 may be transferred onto the second organic layer 180 of the substrate SUB by an electrostatic mechanism, manner or method utilizing an electrostatic head or by a stamp mechanism, manner or method utilizing an elastic polymer material such as PDMS and/or silicon as a transfer substrate.

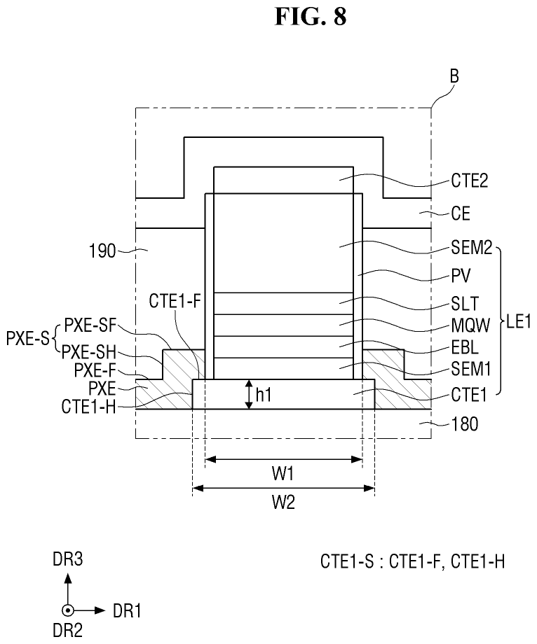

The pixel electrode PXE may be in contact with the side surface of each of the first light-emitting element LE1, the second light-emitting element LE2 and the third light-emitting element LE3. The contact between the light-emitting element and the pixel electrode PXE will be described in more detail later with reference to FIGS. 8 and 9.

The planarization layer 190 may be disposed between the first light-emitting elements LE1, the second light-emitting elements LE2 and the third light-emitting elements LE3. The planarization layer 190 may be a layer for providing a flat surface over (or adjacent to) the first light-emitting elements LE1, the second light-emitting elements LE2 and the third light-emitting elements LE3 having different heights. The planarization layer 190 may be formed of an organic layer such as an acryl resin, an epoxy resin, a phenolic resin, a polyamide resin and/or a polyimide resin.

The common electrode CE may be disposed on the upper surfaces of the first light-emitting elements LE1, the upper surfaces of the second light-emitting elements LE2, the upper surfaces of the third light-emitting elements LE3, and the upper surface of the planarization layer 190. The common electrode CE may be a common layer commonly formed across the first sub-pixel SPX1, the second sub-pixel SPX2 and the third sub-pixel SPX3. The common electrode CE may be made of a transparent conductive material (TCO), such as indium tin oxide (ITO) and/or indium zinc oxide (IZO) that can transmit light.

FIG. 8 is a view showing a pixel electrode, a light-emitting element, a common electrode, and a third planarization layer according to one or more embodiments of the present disclosure. FIG. 8 is an enlarged cross-sectional view of area B of FIG. 7.

Referring to FIG. 8, the first light-emitting element LE1 may include a first contact electrode CTE1, a first semiconductor layer SEM1, an electron blocking layer EBL, an active layer MQW, a superlattice layer SLT, a second semiconductor layer SEM2 and a second contact electrode CTE2. The first semiconductor layer SEM1, the electron blocking layer EBL, the active layer MQW, the superlattice layer SLT and the second semiconductor layer SEM2 may be collectively referred to as a device rod. In one or more embodiments, the first light-emitting element LE1 may further include a passivation layer PV around (e.g., surrounding) the side surface of the device rod.

Referring to FIGS. 7 and 8, the first contact electrode CTE1 may be disposed on the second organic layer 180. The first contact electrode CTE1 and the second organic layer 180 may be bonded to each other by a conductive adhesive member such as an anisotropic conductive film (ACF) and/or an anisotropic conductive paste (ACP). In one or more embodiments, the first contact electrode CTE1 and the second organic layer 180 may be bonded to each other via a laser bonding process. For example, the first contact electrode CTE1 may be formed of one of gold (Au), copper (Cu), aluminum (Al), and/or tin (Sn) or an alloy thereof. According to one or more embodiments of the present disclosure, the height h1 of the first contact electrode CTE1 in the third direction DR3 that is the thickness direction may be approximately (about) 0.5 μm to (about) 3 μm. The first contact electrode CTE1 may be in contact with the pixel electrode PXE on the side surface of the first light-emitting element LE1.

According to one or more embodiments of the present disclosure, the width W2 that is the length of the first contact electrode CTE1 in the first direction DR1 may be greater than the width W1 that is the length of the first semiconductor layer SEM1 in the first direction DR1. The first contact electrode CTE1 includes a protrusion CTE1-S formed to protrude outward from the side surface of the first light-emitting element LE1. The protrusion CTE-S may include a first surface CTE1-F that extends in the first direction DR1 and does not overlap the first semiconductor layer SEM1, and a second surface CTE1-H that extends in the second direction DR2. The first direction is perpendicular to the stacking direction of the device rod. The pixel electrode PXE may be in contact with the second surface CTE1-H and the first surface CTE1-F of the first contact electrode CTE1.

The pixel electrode PXE is disposed on the second organic layer 180 and may be formed along the protrusion CTE-S to cover it. The pixel electrode PXE includes a bottom portion PXE-F having a surface in contact with the second organic layer 180, and a step portion PXE-S formed along the protrusion CTE-S. The step portion PXE-S may include a second step portion PXE-SH formed along the second surface CTE1-H of the first contact electrode CTE1, and a first step portion PXE-SF formed along the first surface CTE1-F of the first contact electrode CTE1. Accordingly, the second step portion PXE-SH may overlap with the second surface CTE1-H of the pixel electrode PXE, and the first step portion PXE-SF may overlap with the first surface CTE1-F of the pixel electrode PXE.

The first semiconductor layer SEM1 may be disposed on the first contact electrode CTE1. The first semiconductor layer SEM1 may be made of GaN doped with p-type or kind dopants such as Mg, Zn, Ca, Se and/or Ba.

The electron blocking layer EBL may be disposed on the first semiconductor layer SEM1. The electron blocking layer EBL may suppress, prevent, or substantially prevent too many electrons from flowing into the active layer MQW. For example, the electron blocking layer EBL may be p-AlGaN doped with p-type or kind Mg. The electron blocking layer EBL may be eliminated or excluded.

The active layer MQW may be disposed on the electron blocking layer EBL. The active layer MQW may be to emit light as electron-hole pairs are combined therein in response to an electrical signal applied through the first semiconductor layer SEM1 and the second semiconductor layer SEM2.

The active layer MQW may include a material having a single or multiple quantum well structure. When the active layer MQW includes a material having the multiple quantum well structure, well layers and barrier layers may be alternately stacked on one another in the structure. The well layers may be made of InGaN, and the barrier layers may be made of GaN or AlGaN, but the present disclosure is not limited thereto. In one or more embodiments, the active layer MQW may have a structure in which a semiconductor material having a large band gap energy and a semiconductor material having a small band gap energy are alternately stacked on one another, and may include other Group III to Group V semiconductor materials depending on the wavelength range of the emitted light.

When the active layer MQW contains InGaN, it may be to emit lights of different colors depending on the content (e.g., amount) of indium (In). For example, as the content (e.g., amount) of indium (In) increases, the wavelength range of light output from the active layers may move to the red wavelength range, and as the content (e.g., amount) of indium (In) decreases, the wavelength range of the light output from the active layer may move to the blue wavelength range. Therefore, the content (e.g., amount) of indium (In) in the active layer MQW of the first light-emitting element LE1 that emits the first light that is light in the red wavelength band may be higher than the content (e.g., amount) of indium (In) in the active layer MQW of the second light-emitting element LE2. The content (e.g., amount) of indium (In) in the active layer MQW of the second light-emitting element LE2 may be higher than the content (e.g., amount) of indium (In) in the active layer MQW of the third light-emitting element LE3. For example, the content (e.g., amount) of indium (In) in the active layer MQW of the first light-emitting element LE1 may range from approximately (about) 30 wt % to (about) 40 wt % (based on 100 wt % of the active layer MQW of the first light-emitting element LE1), the content (e.g., amount) of indium (In) in the active layer MQW of the second light-emitting element LE2 may range from approximately (about) wt % to (about) 30 wt % (based on 100 wt % of the active layer MQW of the second light-emitting element LE2), and the content (e.g., amount) of indium (In) of the third light-emitting element LE3 may range from approximately (about) 10 wt % to (about) 20 wt % (based on 100 wt % of the active layer MQW of the third light-emitting element LE3). In this instance, the active layer MQW of the first light-emitting element LE1 may be to emit the first light, the active layer MQW of the second light-emitting element LE2 may be to emit the second light, and the active layer MQW of the third light-emitting element LE3 may be to emit the third light.

The superlattice layer SLT may be disposed on the active layer MQW. The superlattice layer SLT may relieve stress between the second semiconductor layer SEM2 and the active layer MQW. For example, the superlattice layer SLT may be made of InGaN or GaN. The superlattice layer SLT may be eliminated or excluded.

The second semiconductor layer SEM2 may be disposed on the superlattice layer SLT. The second semiconductor layer SEM2 may be doped with a dopant of a second conductivity-type or kind such as Si, Ge and/or Sn. For example, the second semiconductor layer SEM2 may be n-GaN doped with n-type or kind Si.

The second contact electrode CTE2 may be an ohmic contact electrode. It is, however, to be understood that the present disclosure is not limited thereto. For example, the second contact electrode CTE2 may be a Schottky contact electrode. The second contact electrode CTE2 may include at least one of gold (Au), copper (Cu), aluminum (Al), and/or tin (Sn) or an alloy thereof.

The device rod and the second contact electrode CTE2 may have the same width W1. The first contact electrode CTE1 may protrude farther outward in the first direction DR1 than the second contact electrode CTE2.

The passivation layer PV may be disposed to be around (e.g., surround) the outer surfaces of the first semiconductor layer SEM1, the electron blocking layer EBL, the active layer MQW, the superlattice layer SLT and the second semiconductor layer SEM2. According to one or more embodiments of the present disclosure, the passivation layer PV may be disposed to be around (e.g., surround) at least the outer surface of the active layer MQW, and may be extended in a direction in which the first light-emitting element LE1 extends. The insulating layer PV can protect the above-described elements. For example, the passivation layer PV may be around (e.g., surround) the side surfaces of the above-described elements, exposing both ends of the first light-emitting element LE1 in the longitudinal direction, i.e., at least the first contact electrode CTE1 and the second contact electrode CTE2.

The thickness of the passivation layer PV may be in, but is not limited to, the range of approximately (about) 10 nm to (about) 1.0 μm. In one or more embodiments, the thickness of the passivation layer PV may be approximately (about) 40 nm.

The passivation layer PV may include materials having an insulating property such as silicon oxide (SiOx), silicon nitride (SiNx), silicon oxynitride (SiOxNy), aluminum nitride (AlN) and/or aluminum oxide (Al₂O₃). Accordingly, it is possible to prevent or substantially prevent an electrical short-circuit that may occur when the active layer MQW comes in contact with an electrode through which an electric signal is transmitted to the first light-emitting element LE1. In one or more embodiments, because the passivation layer PV protects the outer surface of the first light-emitting element LE1, including the active layer MQW, it is possible to prevent or reduce a decrease in luminous efficiency.

In addition, in one or more embodiments, the outer surface of the passivation layer PV may be subjected to a surface treatment. The first light-emitting elements LE1 may be dispersed in an ink and the ink may be sprayed onto the electrode so that they are aligned during the process of fabricating the display device 10. In doing so, a surface treatment may be applied to the passivation layer PV so that it becomes hydrophobic or hydrophilic in order to keep the first light-emitting elements LE1 dispersed in the ink from being aggregated with adjacent second light-emitting elements LE2.

Although the first light-emitting element LE1 is described in FIG. 8, the second light-emitting element LE2 and the third light-emitting element LE3 also may have the same structure as the first light-emitting element LE1; and, therefore, the redundant descriptions may not be provided.

FIG. 9 is a cross-sectional view showing a pixel electrode, a light-emitting element, a common electrode and a third planarization layer according to a modification of the embodiment of FIG. 8, according to one or more embodiments of the present disclosure.

Because a pixel electrode and a first contact electrode CTE1 of FIG. 9 and are different from those of FIG. 8, the different elements will be mainly described.

According to one or more embodiments of the present disclosure, the first contact electrode CTE1 may be made up of a single layer or multiple layers of one or more of gold (Au), copper (Cu), aluminum (Al), and/or tin (Sn) or an alloy thereof. Although the first contact electrode CTE1 is made up of a double layer in the example shown in FIG. 9, the number of layers is not limited thereto.

Referring to FIG. 9, a first contact electrode CTE1 may include a first sub-contact electrode CTE1-1 and a second sub-contact electrode CTE1-2.

The second sub-contact electrode CTE1-2 may be disposed on a second organic layer 180, and the first sub-contact electrode CTE1-1 may be disposed on the second sub-contact electrode CTE1-2.

A first semiconductor layer SEM1 is disposed on one surface of the first sub-contact electrode CTE1-1, and the second sub-contact electrode CTE1S2 is disposed on the opposite surface to the one surface.

One surface of the second sub-contact electrode CTE1-2 is in contact with the first sub-contact electrode CTE1-1, and the opposite surface to the one surface is in contact with the second organic layer 180.

The first sub-contact electrode CTE1-1 has a height h2 of approximately (about) 0.5 μm to (about) 2.5 μm in the third direction DR3 that is the thickness direction. The second sub-contact electrode CTE1-2 has a height h3 of approximately (about) 0.5 μm to (about) 2.5 μm in the third direction DR3 that is the thickness direction, the sum of the height h2 of the first sub-contact electrode CTE11 and the height h3 of the second sub-contact electrodes CTE1-2 may be approximately (about) 1 μm to (about) 3 μm. That is to say, the height h4 of the first contact electrode CTE1 may be approximately (about) 1 μm to (about) 3 μm.

The first sub-contact electrode CTE1-1 has a width W2-1 greater than the width W1 of the first semiconductor layer SEM1 including the passivation layer PV. The first sub-contact electrode CTE1-1 includes a first protrusion CTE-S1 protruding outward from a side surface of the first light-emitting element LE1. The protrusion CTE-S1 does not overlap the first semiconductor layer SEM1 but is exposed.

The second sub-contact electrode CTE1-2 has a width W2-2 greater than the width W2-1 of the first sub-contact electrode CTE1-1. The second sub-contact electrode CTE1-2 includes a second protrusion CTE-S2 protruding outward from a side surface of the first sub-contact electrode CTE1-1. The second protrusion CTE-S2 does not overlap with the first sub-contact electrode CTE1-1 but is exposed.

The first protrusion CTE-S1 of the first sub-contact electrode CTE1-1 and the second protrusion CTE-S2 of the second sub-contact electrode CTE1-2 of the first contact electrode CTE1 may be in contact with the pixel electrode PXE.

The pixel electrode PXE is disposed on the second organic layer 180 and extends along the first protrusion CTE-S1 and the second protrusion CTE-S2 to cover them. The pixel electrode PXE may include a floor portion PXE-F and a step portion PXE-S. The floor portion PXE-F of the pixel electrode PXE may be formed along the second organic layer 180. The step portion PXE-S may include a first step PXE-S1 formed along the first protrusion CTE-S1 of the first contact electrode CTE1 and a second step PXE-S2 formed along the second protrusion CTE-S2 of the first contact electrode CTE1. Accordingly, the second step PXE-S2 overlaps the second protrusion CTE-S2 of the first contact electrode CTE1, and the first step PXE-S1 overlaps the first protrusion CTE-S1 of the first contact electrode CTE1.

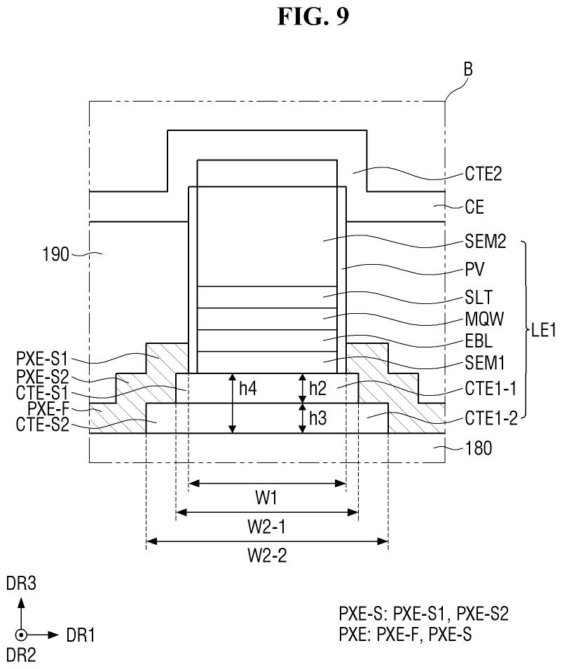

Referring to FIG. 10, a first contact electrode CTE1 may not protrude outward from a side surface of a first light-emitting element LE1. Also in this instance, the first contact electrode CTE1 may be disposed on a second organic layer 180. In one or more embodiments, the first contact electrode CTE1 may be in contact with a pixel electrode PXE on a side surface of the first light-emitting element LE1. The height h1 of the first contact electrode CTE1 in the third direction DR3 that is the thickness direction may be approximately (about) 0.5 μm to (about) 3 μm.

According to one or more embodiments of the present disclosure, the width W2 that is the length of the first contact electrode CTE1 in the first direction DR1 may be equal to the width W1 that is the length of the first semiconductor layer SEM1 (or, in some embodiments, the first semiconductor layer SEM1 plus the passivation layer PV) in the first direction DR1.

The pixel electrode PXE is disposed on the second organic layer 180 and is in contact with the first light-emitting element LE1. The pixel electrode PXE may have a height equal to or higher than the height h1 of the first contact electrode CTE1.

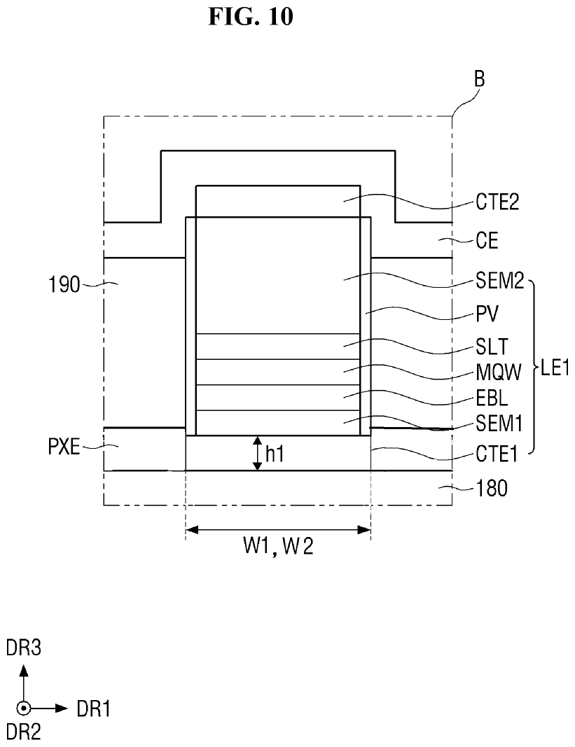

FIG. 11 is a cross-sectional view showing a modification of the embodiment(s) of FIG. 7, according to one or more embodiments of the present disclosure. Because a pixel electrode PXE and a second pixel connection electrode PCE2 of FIG. 11 are different from those of FIG. 7, the different elements will be mainly described. Like reference numerals to those used in FIG. 7 denote like elements, and redundant descriptions of such elements may not be repeated.

FIG. 11 is a cross-sectional view showing an example of the display panel taken along line A-A′ of FIG. 6.

Referring to FIGS. 6 and 11, an emission material layer EML may be disposed on the second organic layer 180. The emission material layer EML may include pixel electrodes PXE, light-emitting elements LE1, LE2 and LE3, a common electrode CE, and a planarization layer 190.

Each of the plurality of sub-pixels SPX1, SPX2 and SPX3 may have one or more third pixel connection holes PCT3 penetrating through the second organic layer 180. Each of the third pixel connection holes PCT3 exposes the second pixel connection electrode PCE2.

Referring to FIGS. 6 and 11, the first sub-pixel SPX1 has two third pixel connection holes PCT3-1 and PCT3-2.

At least a part of the third pixel connection hole PCT3-2 may be exposed by the first light-emitting elements LE1 disposed in the first sub-pixel SPX1. In one or more embodiments, the first light-emitting element LE1 and the third pixel connection hole PCT3-1 may overlap each other at least partially.

The third pixel connection hole PCT3-2 is exposed without overlapping the first light-emitting elements LE1. The pixel electrode PXE may be connected to the second pixel connection electrode PCE2 through the third pixel connection hole PCT3-2.

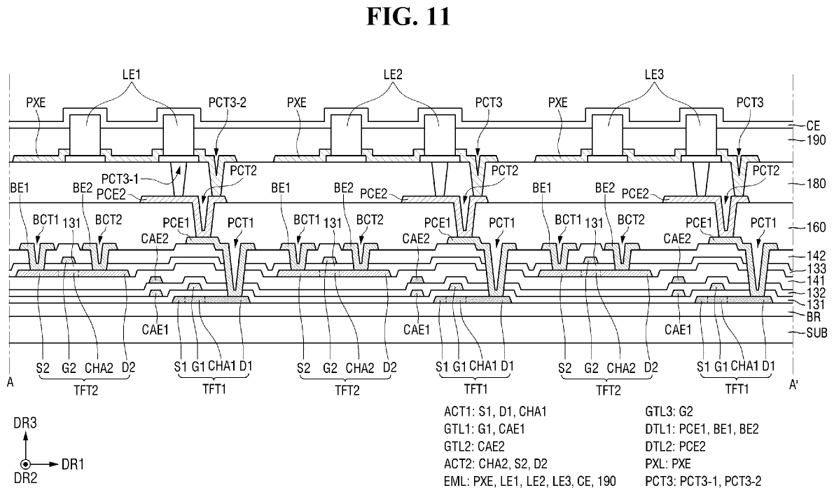

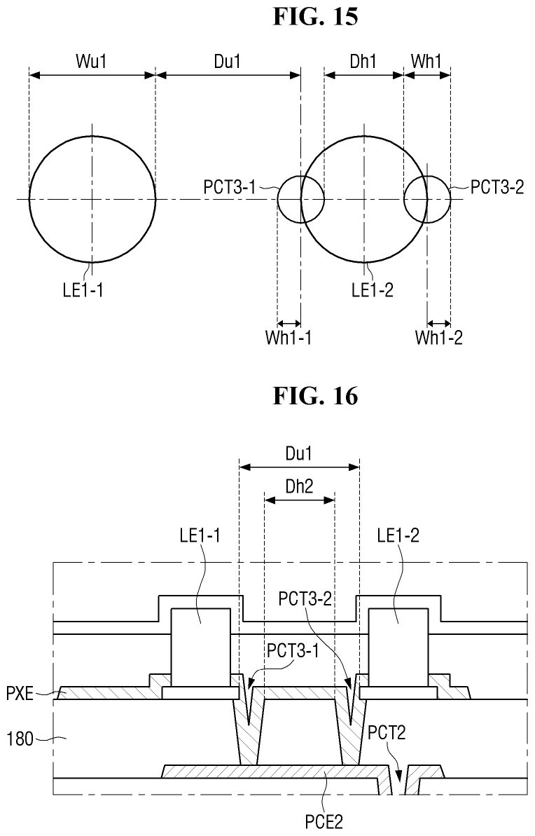

Hereinafter, the third pixel connection holes PCT3-1 and PCT3-2 will be described in more detail with reference to FIGS. 12 to 17.

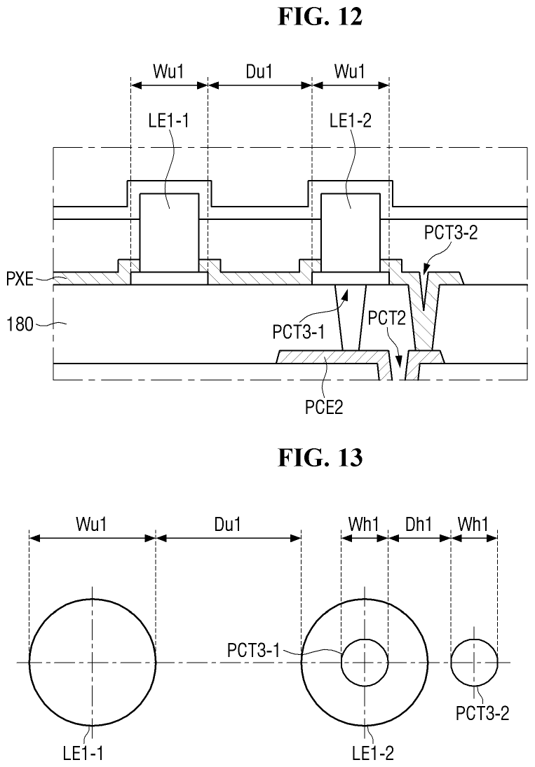

FIG. 12 is a cross-sectional view showing a pixel electrode, light-emitting elements, a common electrode, and a third planarization layer included in the first sub-pixel SPX1 of FIG. 11. FIGS. 13 to 15 are plan views showing the light-emitting elements and the pixel connection holes of FIG. 12.

Referring to FIGS. 11 to 15, a first sub-pixel SPX1 includes a (1-1) light-emitting element LE1-1 and a (1-2) light-emitting element LE1-2. In one or more embodiments, the first sub-pixel SPX1 includes a (3-1) pixel connection hole PCT3-1 and a (3-2) pixel connection hole PCT3-2.

According to one or more embodiments of the present disclosure, at least one of the (3-1) pixel connection hole PCT3-1 and/or the (3-2) pixel connection hole PCT3-2 overlaps with the (1-2) light-emitting element LE1-1.

The (1-1) light-emitting element LE1-1 and the (1-2) light-emitting element LE1-2 may have the same width Wu1. The width Wu1 may be, but is not limited to, approximately (about) 3 μm to (about) 10 μm. The (3-1) pixel connection hole PCT3-1 and the (3-2) pixel connection hole PCT3-2 may have the same width Wh1. The width Wh1 of the (3-1) pixel connection hole PCT3-1 may be smaller than the width Wu1 of the (1-1) light-emitting element LE1-1.

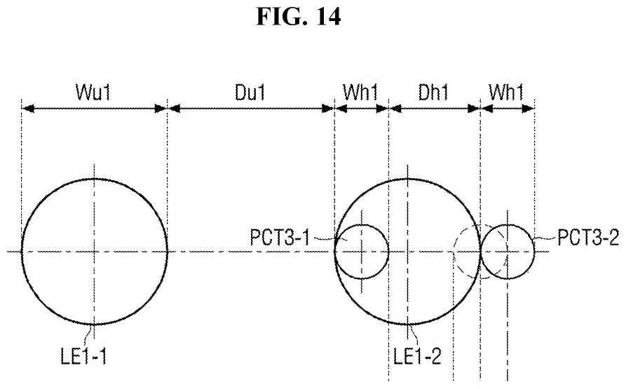

Referring to FIG. 14, the distance Dh1 between the (3-1) pixel connection hole PCT3-1 and the (3-2) pixel connection hole PCT3-2 is greater than the difference between the width Wu1 of the (1-1) light-emitting element LE1-1 and the width Wh1 of the (3-1) pixel connection hole PCT3-1, and is less than the difference between the distance Du1 between the (1-1) light-emitting element LE1-1 and the (1-2) light-emitting element LE1-1 and the width Wh1 of the (3-1) pixel connection hole PCT3-1. For example, as shown in FIG. 14, when the (3-1) pixel connection hole PCT3-1 is inscribed in the (1-1) light-emitting element LE1-1, in order for the (3-2) pixel connection hole PCT3-2 not to overlap the first light-emitting element LE1-2, the distance Dh1 should be greater than the difference between the width Wu1 of the (1-1) light-emitting element LE1-1 and the width Wh1 of the (3-1) pixel connection hole PCT3-1.

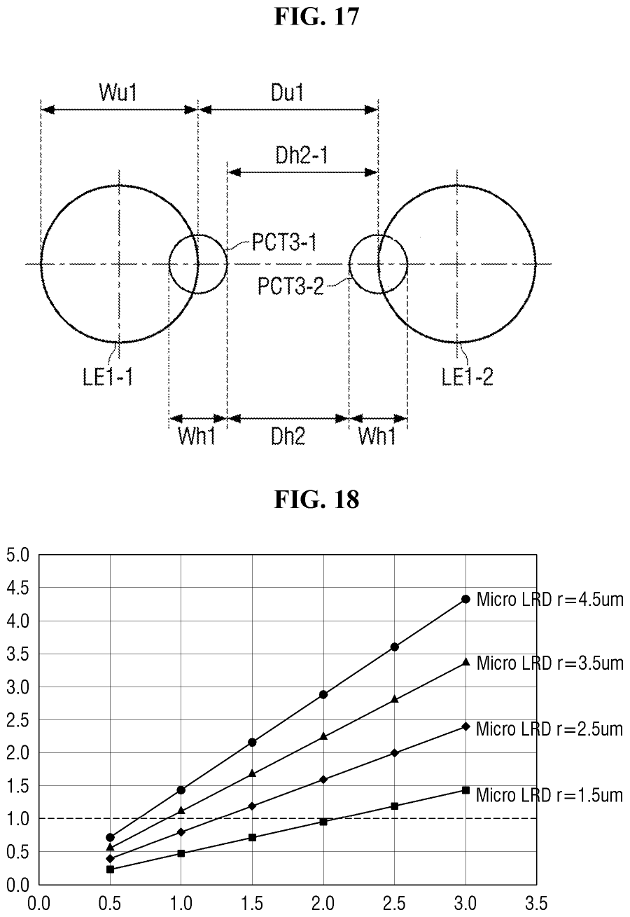

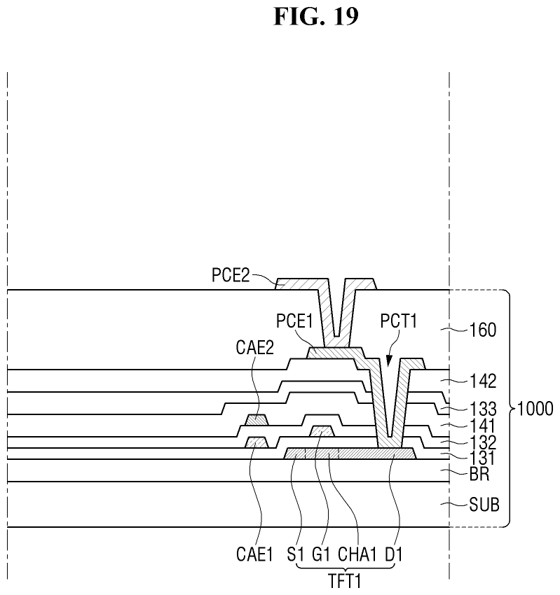

FIG. 16 is a view showing a pixel electrode, light-emitting elements, a common electrode, and a third planarization layer included in the first sub-pixel SPX1 of FIG. 11 according to another modification. FIG. 17 is a plan view showing the light-emitting elements and the connection electrodes of FIG. 16.

Referring to FIGS. 16 and 17, a first sub-pixel SPX1 includes a (1-1) light-emitting element LE1-1 and a (1-2) light-emitting element LE1-2. In one or more embodiments, the first sub-pixel SPX2 includes a (3-1) pixel connection hole PCT3-1 and a (3-2) pixel connection hole PCT3-2.

According to one or more embodiments of the present disclosure, the (3-1) pixel connection hole PCT3-1 and the (3-2) pixel connection hole PCT3-2 may be located between the (1-1) light-emitting element LE1-1 and the (1-2) light-emitting element LE1-1.

The (1-1) light-emitting element LE1-1 and the (1-2) light-emitting element LE1-1 may have the same width Wu1. The width Wu1 may be, but is not limited to, approximately (about) 3 μm to (about) 10 μm. The (3-1) pixel connection hole PCT3-1 and the (3-2) pixel connection hole PCT3-2 may have the same width Wh1. The width Wh1 of the (3-1) pixel connection hole PCT3-1 may be smaller than the width Wu1 of the (1-1) light-emitting element LE1-1.

The distance Dh2 between the (3-1) pixel connection hole PCT3-1 and the (3-2) pixel connection hole PCT3-2 is greater than the difference between the width Wu1 of the (1-1) light-emitting element LE1-1 and the width Wh1 of the (3-1) pixel connection hole PCT3-1, and is less than the difference between the distance Du1 between the (1-1) light-emitting element LE1-1 and the (1-2) light-emitting element LE1-1 and the width Wh1 of the (3-1) pixel connection hole PCT3-1.

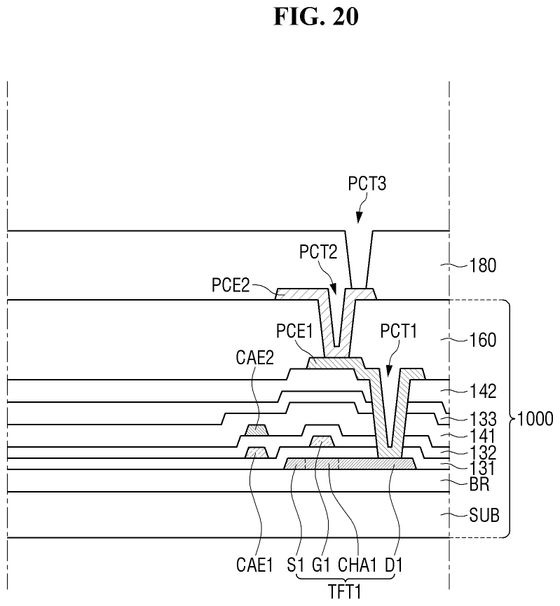

FIG. 18 is a graph showing a relationship between the thickness of the first contact electrode CTE1 of the first light-emitting element LE1 of FIGS. 1 to 11 and the contact area of the pixel electrode PXE.

In the graph shown in FIG. 18, the horizontal axis represents the thickness (μm) of the first contact electrode CTE1 of the first light emitting element LE1, and the thickness (μm) of the second contact electrode CTE2. The vertical axis represents the ratio of a contact area between the first contact electrode CTE1 and the pixel electrode PXE to a contact area between the first contact electrode CTE1 and the second organic layer 180.

For example, when the radius of the first light-emitting element LE1 is approximately (about) 4.5 μm and the thickness (μm) of the first contact electrode CTE1 of the first light-emitting element LE1 is approximately (about) 0.7 μm or more, the contact area between the first contact electrode CTE1 and the pixel electrode PXE is equal to or greater than the contact area between the first contact electrode CTE1 and the second organic layer 180.

When the radius of the first light-emitting element LE1 is approximately (about) 3.5 μm and the thickness (μm) of the first contact electrode CTE1 of the first light-emitting element LE1 is approximately (about) 0.9 μm or more, the contact area between the first contact electrode CTE1 and the pixel electrode PXE is equal to or greater than the contact area between the first contact electrode CTE1 and the second organic layer 180.

When the radius of the first light-emitting element LE1 is approximately (about) 2.5 μm and the thickness (μm) of the first contact electrode CTE1 of the first light-emitting element LE1 is approximately (about) 1.25 μm or more, the contact area between the first contact electrode CTE1 and the pixel electrode PXE is equal to or greater than the contact area between the first contact electrode CTE1 and the second organic layer 180.

When the radius of the first light-emitting element LE1 is approximately (about) 1.5 μm and the thickness (μm) of the first contact electrode CTE1 of the first light-emitting element LE1 is approximately (about) 2.0 μm or more, the contact area between the first contact electrode CTE1 and the pixel electrode PXE is equal to or greater than the contact area between the first contact electrode CTE1 and the second organic layer 180.

As can be seen from FIG. 18, by adjusting the height of the first light-emitting element LE1, it is possible to achieve that the contact area between the first contact electrode CTE1 and the pixel electrode PXE is equal to or greater than the contact area between the first contact electrode CTE1 and the organic layer 180.

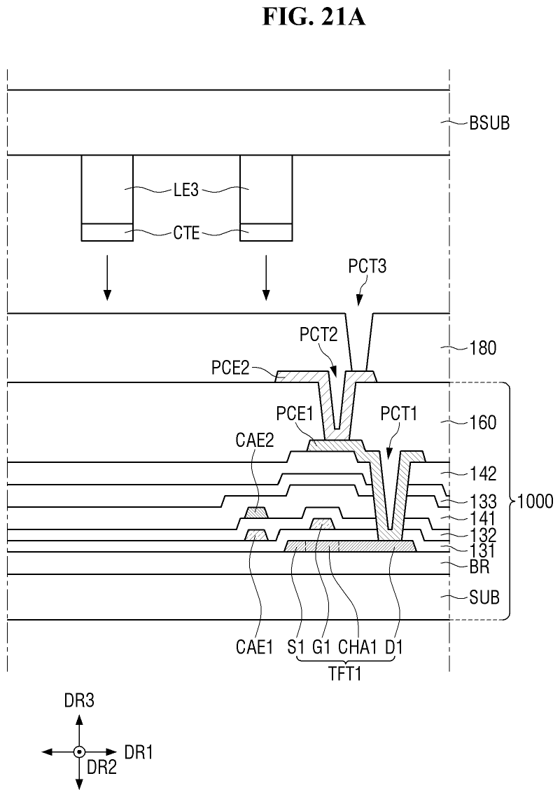

FIGS. 19 to 27 are cross-sectional views showing some of the processing steps of fabricating a display device according to one or more embodiments of the present disclosure.

Initially, referring to FIG. 19, a first substrate SUB is prepared and a circuit layer 100 is formed on the first substrate SUB. The circuit layer 1000 includes a plurality of conductive layers and insulating layers. In one or more embodiments, the circuit layer 1000 may include a barrier layer BR, a first thin-film transistor TFT1, a first capacitor electrode CAE1, a second capacitor electrode CAE2, and one or more pixel connection electrodes PCE1 and PCE2. The first capacitor electrode CAE1 and a first gate electrode G1 may be disposed on the first gate insulator 131. The second capacitor electrode CAE2 may be disposed on the second gate insulator 132. A plurality of insulating layers 141, 133 and 142 is disposed on the second gate insulator 132, a first pixel connection hole PCT1 penetrating through the plurality of insulating layers is formed, and a pixel connection electrode PCE1 is disposed on the first pixel connection hole PCT1. The first pixel connection electrode PCE1 is connected to a first drain region D of the first thin-film transistor TFT1 through the first pixel connection hole PCT1. Such structures have been described above with reference to FIG. 7.

A first organic layer 160 is formed over the insulating layers on which the first pixel connection electrode PCE1 is formed. When the first organic layer 160 is formed, a second pixel connection hole PCT2 is formed, which penetrates through the first organic layer 160 to expose the first pixel connection electrode PCE1. A second pixel connection electrode PCE2 is disposed on the first pixel connection hole PCT1. Each of the conductive layers and the insulating layers may be formed by generally available deposition and patterning process. Hereinafter, the order of forming the layers will be described in more detail.

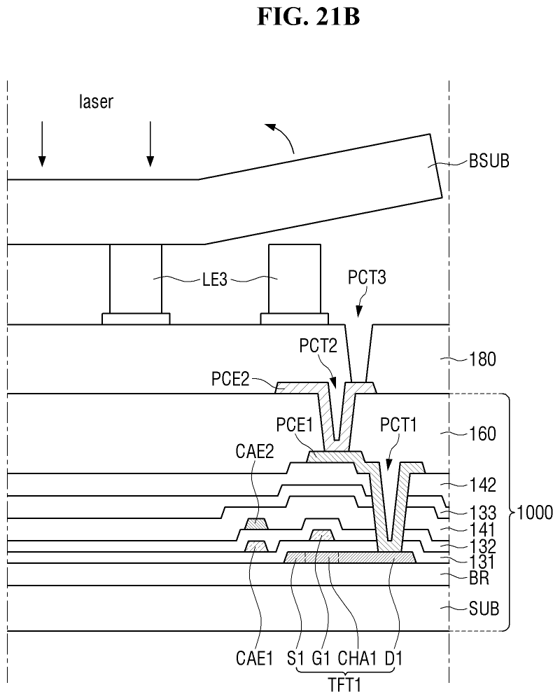

Subsequently, referring to FIG. 20, a second organic layer 180 is formed over the first organic layer 160 on which the second pixel connection electrode PCE2 is formed. When the second organic layer 180 is formed, one or more third pixel connection holes PCT3 are formed, which penetrate through the second organic layer 180 to expose the second pixel connection electrode PCE2.

Although one third pixel connection hole PCT3 is depicted in FIG. 20, a plurality of third pixel connection holes PCT3 may be formed, as shown, e.g., in FIG. 11. Even when a plurality of third pixel connection holes PCT3 is formed, each of the third pixel connection holes PCT3 penetrates through the first organic layer 160 to expose the second pixel connection electrode PCE2. The distance between the third pixel connection holes PCT3 has been described above with reference to FIGS. 13 to 17.

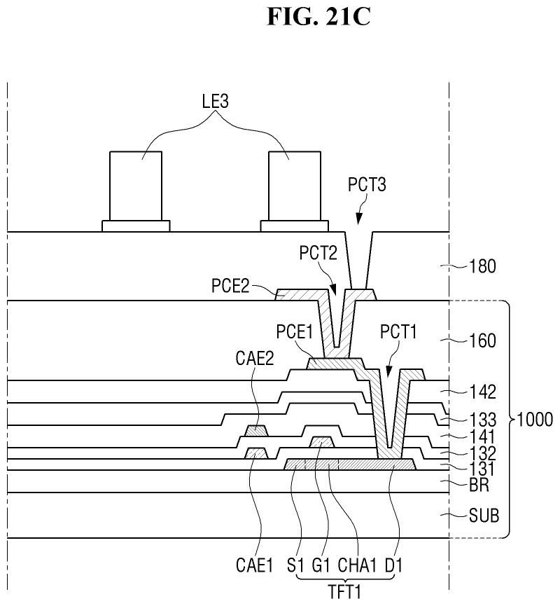

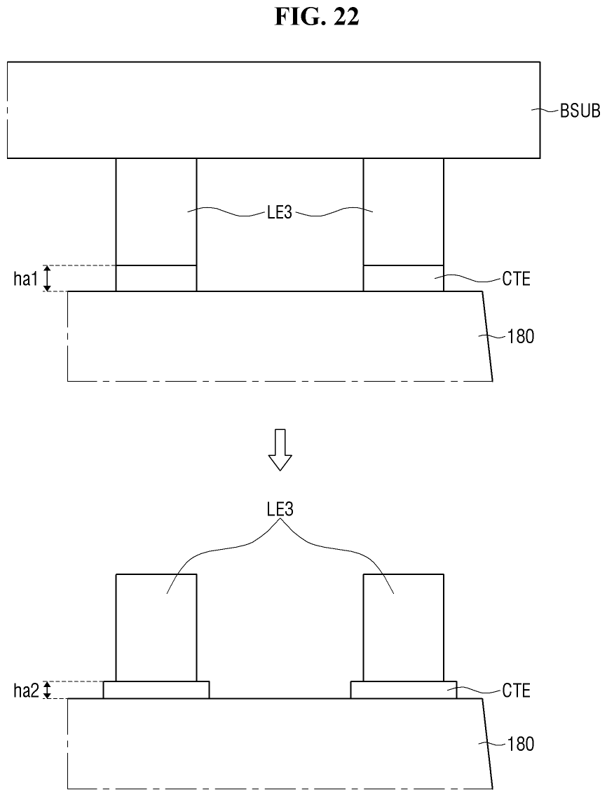

Subsequently, referring to FIGS. 21A, 21B, 21C and 22, the light-emitting elements LE3 are bonded on the second organic layer 180.

A base substrate BSUB having light-emitting elements LE3 formed thereon is prepared. As described above, the light-emitting elements LE3 include a plurality of semiconductor material layers formed by growing seed crystals by epitaxial growth. The method of forming the semiconductor material layer may include an electron beam deposition method, physical vapor deposition (PVD), chemical vapor deposition (CVD), plasma laser deposition (PLD), dual-type or kind thermal evaporation, sputtering, metal-organic chemical vapor deposition (MOCVD), etc. In one or more embodiments, the method may be carried out by metal-organic chemical vapor deposition (MOCVD). It is, however, to be understood that the present disclosure is not limited thereto.

A precursor material for forming the plurality of semiconductor material layers is not particularly limited and any typical material suitable in the art may be selected as long as it can form a target material. For example, the precursor material may be a metal precursor including an alkyl group such as a methyl group or an ethyl group. For example, it may be, but is not limited to, a compound such as trimethyl gallium (Ga(CH₃)₃), trimethyl aluminum (Al(CH₃)₃), or triethyl phosphate ((C₂H₅)₃PO₄). The light-emitting element LE3 includes a contact electrode CTE made of one or more of gold (Au), copper (Cu), aluminum (Al) and/or tin (Sn) or an alloy thereof.

The base substrate BSUB having the light-emitting element LE3 formed thereon is aligned above the substrate SUB. In doing so, the contact electrodes CTE of the light-emitting elements LE3 formed on the base substrate BSUB face the substrate SUB.

Subsequently, the substrate SUB and the base substrate BSUB are attached together. For example, the contact electrodes CTE of the light-emitting elements LE formed on the base substrate BSUB are brought into contact with the second organic layer 180 of the first substrate 110. At this time, the contact electrodes CTE of the light-emitting elements LE3 are brought into contact with the second organic layer 180 of the first substrate 110.

The second organic layer 180 and the first contact electrodes CTE1 of the light-emitting elements LE3 are bonded to each other. In doing so, the plurality of light-emitting elements LE are attached to the upper surface of the second organic layer 180. For fusion bonding, a laser may be irradiated to the second organic layer 180 from above the base substrate BSUB. After the laser is irradiated to the second organic layer 180, high heat of the laser is conducted to the second organic layer 180, so that the interface with the first contact electrodes CTE1 of the light-emitting elements LE can be attached.

Subsequently, the base substrate BSUB is separated from the plurality of light-emitting elements LE.

The process of separating the base substrate BSUB may be carried out by utilizing a laser lift-off (LLO) technology. The laser lift-off process uses a laser, and a KrF excimer laser (wavelength of 248 nm) may be utilized as the source. It should be understood, however, that the present disclosure is not limited thereto. When the laser is irradiated onto the base substrate BSUB, the base substrate BSUB may be separated from the light-emitting elements LE.

Accordingly, a plurality of light-emitting elements LE may be disposed on the pixel electrode layer PXL.

The height ha2 of the first contact electrode CTE1 after pressurization and laser irradiation is lower than the height ha1 of the first contact electrode CTE1 before pressurization and laser irradiation. The width of the first contact electrode CTE1 is increased compared to its width before the laser irradiation. The first contact electrode CTE1 may protrude outward from the light-emitting element (e.g., the third light emitting element LE3).

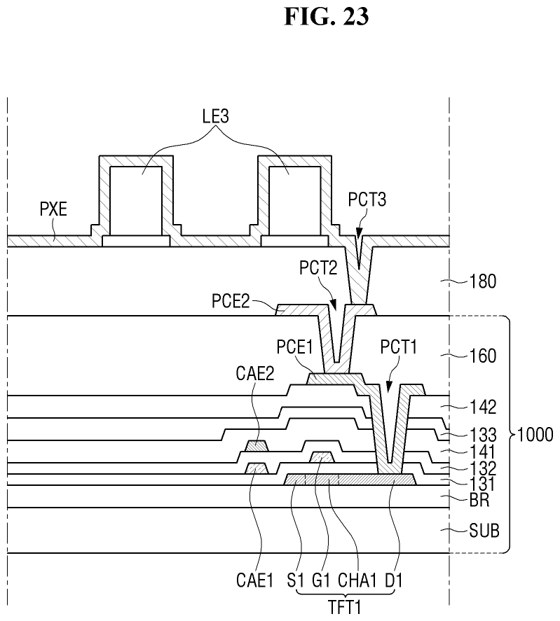

Referring to FIGS. 23 to 26, a material for forming the pixel electrode PXE is disposed on the second organic layer 180 where the light-emitting element LE3 is bonded.

To this end, as shown in FIG. 23, the material of the pixel electrode PXE is disposed along the light-emitting element LE3 to cover the second organic layer 180.

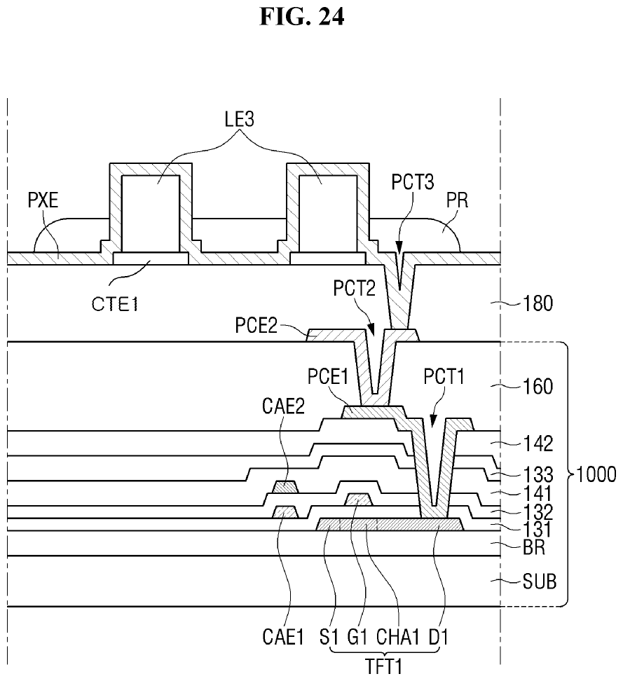

Subsequently, as shown in FIG. 24, a photoresist PR is patterned by applying a photoresist PR on the pixel electrode PXE, exposing it of the light, and developing it. The photoresist PR is applied to entirely cover the first contact electrode CTE1 protruding outward from the light-emitting element LE3 and to cover the third pixel connection hole PCT3. The photoresist PR is applied so as not to cover the upper portion of the light-emitting element LE3.

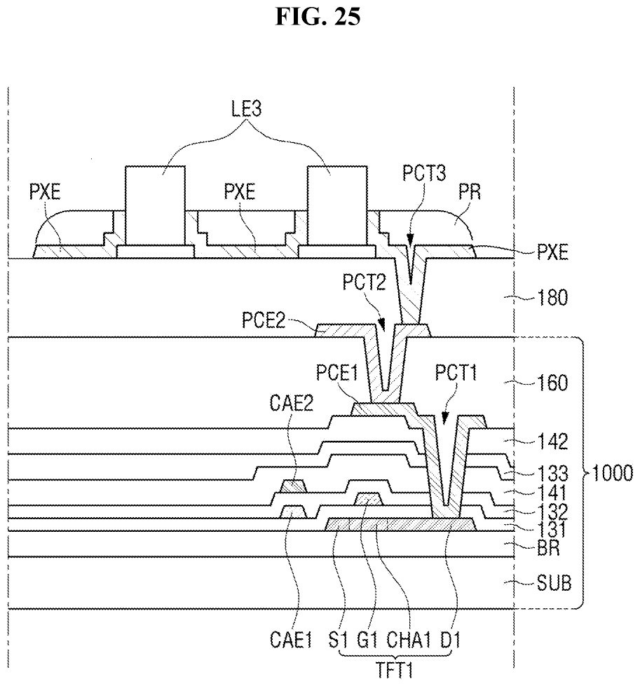

Subsequently, as shown in FIG. 25, the pixel electrode PXE is patterned by removing portions not covered with the photoresist. The pixel electrode PXE is in contact with the first contact electrode CTE1 protruding outward from the light-emitting element LE3 and is electrically connected to it. In one or more embodiments, the pixel electrode PXE may be electrically connected to the second pixel connection electrode PCE2 through the third pixel connection hole PCT3-2.

According to this embodiment, the light-emitting elements are bonded and then the pixel electrode PXE is formed thereon, instead of bonding the light-emitting elements on the pixel electrode PXE. Therefore, no process of applying Flux when the pixel electrode is formed, or no process of removing an oxide layer generated on the pixel electrode is required.

In one or more embodiments, the material of the pixel electrode PXE is not particularly limited, and accordingly a material having a high reflectance may be employed.

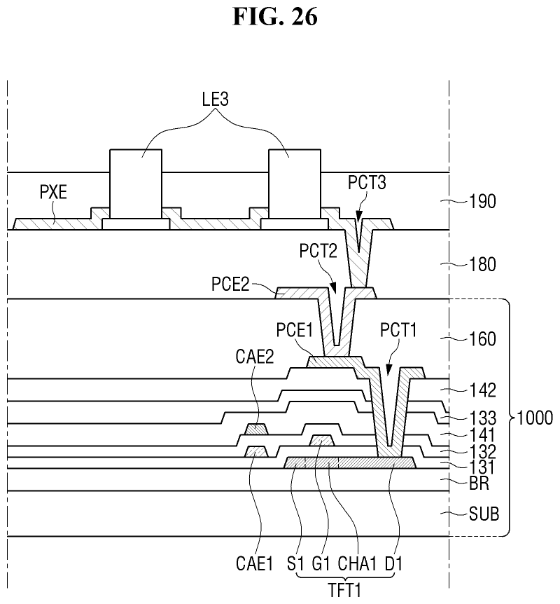

Subsequently, as shown in FIG. 26, a planarization layer 190 is formed between the light-emitting elements after the pixel electrodes PXE have been formed, which is patterned so that the second contact electrodes CTE2 (see, e.g., FIG. 8) of the light-emitting elements LE3 are exposed. The planarization layer 190 may fix the light-emitting elements LE3.

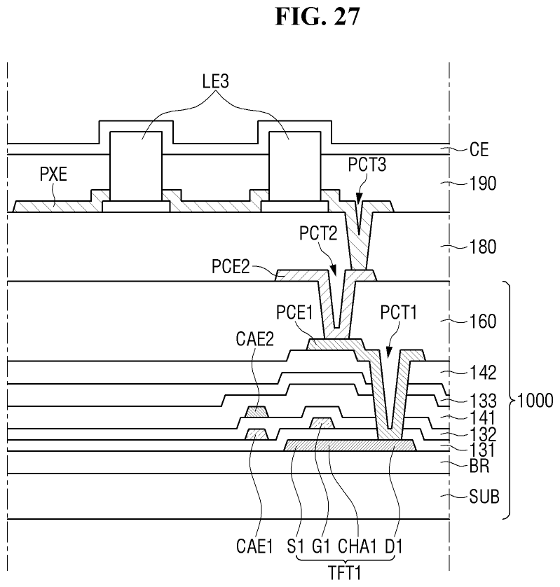

As shown in FIG. 27, a common electrode CE is disposed on the planarization layer 190.

The common electrode CE is electrically connected to the second contact electrode CTE2 of each of the light-emitting elements LE3.

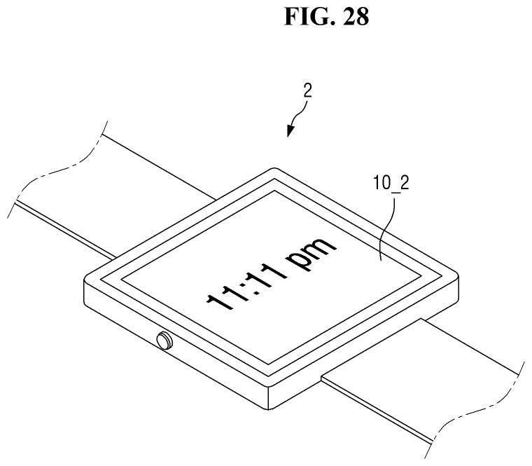

FIG. 28 is a perspective view of a smart device including a display device according to one or more embodiments of the present disclosure.

Referring to FIG. 28, a display device 10_2 according to, for example, the embodiment of FIG. 1 may be applicable to a smartwatch 2, which is a type or kind of smart device. The smartwatch 2 may generally have a rectangular shape except for a wristband, in a plan view. For example, the planar shape of the display unit of the smart watch 2 may conform to the planar shape of the display device 10_2.

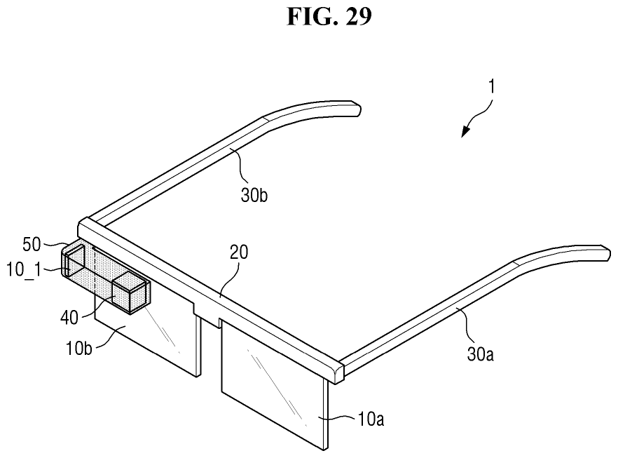

FIG. 29 is a perspective view of a virtual reality (VR) device a display device according to one or more embodiments of the present disclosure. FIG. 29 illustrates a VR device 1, to which a display device 10_1 according to the embodiment of, for example, FIG. 1 is applied.

Referring to FIG. 29, the VR device 1 may be an eyeglass-type or kind device. The VR device 1 may include the display device 10_1, a left-eye lens 10a, a right-eye lens 10b, a support frame 20, eyeglass temples 30a and 30b, a reflective member 40, and a display device storage compartment 50.

FIG. 29 illustrates the VR device 1 including the eyeglass temples 30a and but the VR device 1 may also be applicable to a head-mounted display (HMD) including a headband that can be worn on the head, instead of the eyeglass temples 30a and 30b. For example, the VR device 1 is not particularly limited to that illustrated in FIG. 29 and may be applicable to one or more suitable types (kinds) of electronic devices.

The display device storage compartment 50 may include the display device 10_1 and the reflective member 40. An image displayed by the display device 10_1 may be reflected by the reflective member 40 and may thus be provided to the right eye of a user through the right-eye lens 10b. Thus, the user may view a VR image, displayed by the display device 10_1, through his or her right eye.

FIG. 29 illustrates that the display device storage compartment 50 is disposed at the right end of the support frame 20, but the present disclosure is not limited thereto. In one or more embodiments, the display device storage compartment may be disposed at the left end of the support frame 20, in which case, an image displayed by the display device 10_1 may be reflected by the reflective member 40 and may thus be provided to the right eye of the user through the left-eye lens 10a. In one or more embodiments, two display device storage compartments 50 may be disposed at both (e.g., simultaneously) the left and right ends of the support frame 20, in which case, the user may view a VR image, displayed by the display device 10_1, through both (e.g., simultaneously) his or her left and right eyes.

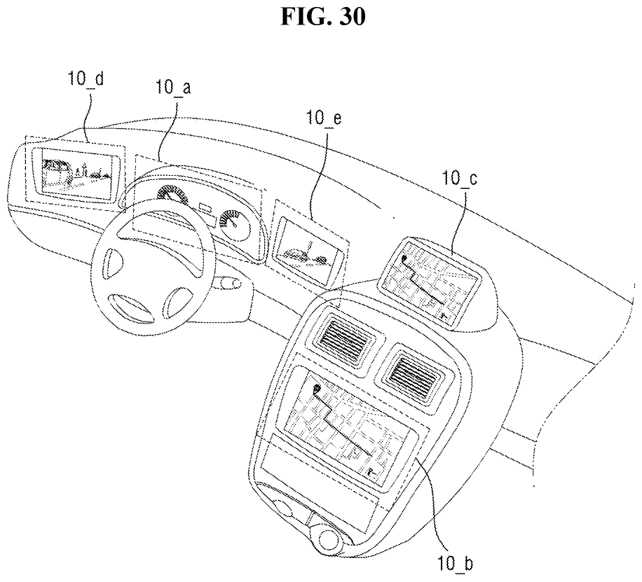

FIG. 30 is a perspective view of a dashboard and a center console of an automobile including display devices according to one or more embodiments of the present disclosure. FIG. 30 illustrates an automobile, to which display devices 10_a, 10_c, 10_d, and 10_e according to the embodiment of, for example, FIG. 1 are applied.

Referring to FIG. 30, the display devices 10_a, 10_b, and 10_c may be applicable to the dashboard or center console of an automobile or to a center information display (CID) in the dashboard of an automobile. The display devices and 10_e may be applicable to room mirror displays that can replace the rear view mirrors of an automobile.

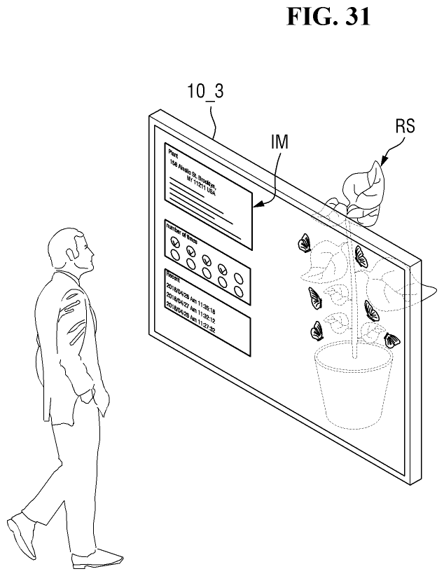

FIG. 31 is a transparent display device including a display device according to one or more embodiments of the present disclosure.

Referring to FIG. 31, a display device 10_3 according to, for example, the embodiment of FIG. 1 may be applicable to a transparent display device. The transparent display device may display an image IM and at the same time, transmit light therethrough. Thus, a user at the front of the transparent display device may view not only the image IM on the display device 10_3, but also an object RS or the background at the rear of the transparent display device. In a case where the display device 10_3 is applied to the transparent display device, a substrate SUB of the display device 10_3 may include light-transmitting parts capable of transmitting light therethrough or may be formed of a material capable of transmitting light therethrough.

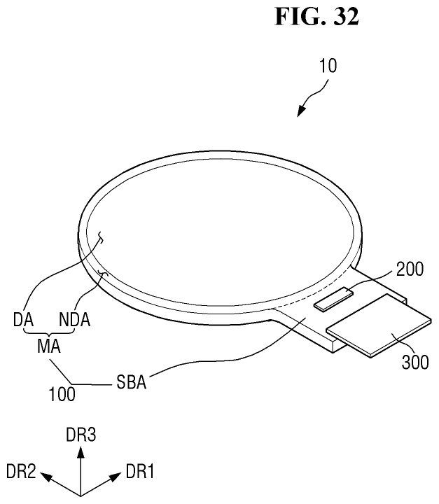

FIG. 32 is a perspective view of a display device according to one or more embodiments of the present disclosure.

The embodiment of FIG. 32 differs from the embodiment of FIG. 1 only in that a display area DA and a main area MA of a display panel 100 have a circular shape in a plan view, and thus, a detailed description thereof may not be provided.

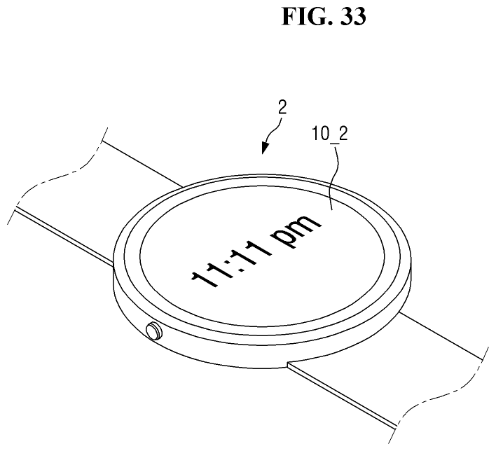

FIG. 33 is a perspective view of a smart device including the display device of FIG. 32.

Referring to FIG. 33, a smartwatch 2 generally has a circular shape except for a wristband. For example, the planar shape of display unit of the smartwatch may conform to the planar shape of a display device 10_2.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Further, the use of “may” when describing embodiments of the present disclosure refers to “one or more embodiments of the present disclosure.” As used herein, the singular forms “a,” “an” and “the” are intended to include the plural forms as well, unless the context clearly indicates otherwise.

The light emitting device, electronic apparatus or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure

Although the embodiments of the present disclosure have been described, it is understood that the present disclosure should not be limited to these embodiments, but one or more suitable changes and modifications can be made by one ordinary skilled in the art within the spirit and scope of the present disclosure as defined by the following claims and equivalents thereof.

What is claimed is:

1. A display device comprising:
a substrate;
a thin-film transistor on the substrate and comprising a first electrode, a second electrode and a semiconductor layer;
a first insulating layer on the thin-film transistor;
an organic layer on the first insulating layer;
at least one light-emitting element on the organic layer;
a pixel electrode on the organic layer and in contact with a side surface of the at least one light-emitting element;
a planarization layer on the side surface of the at least one of light-emitting element; and
a common electrode on the at least one light-emitting element and the planarization layer.

2. The display device of claim 1, wherein the at least one light-emitting element comprises
a first contact electrode on the organic layer and in contact with the pixel electrode on the side surface;
a device rod overlapping the first contact electrode; and
a second contact electrode overlapping the device rod and in contact with the common electrode.

3. The display device of claim 2, wherein the first contact electrode comprises a protrusion protruding outward from the device rod in a first direction,
wherein the pixel electrode is arranged along the protrusion, and
wherein the first direction is perpendicular to a stack direction of the device rod.

4. The display device of claim 2, wherein the first contact electrode further comprises a first sub-contact electrode and a second sub-contact electrode,
wherein the first sub-contact electrode comprises a first protrusion protruding outward from the device rod in a first direction, and the second sub-contact electrode comprises a second protrusion protruding outward from the device rod in the first direction, and
wherein the first direction is perpendicular to a stacking direction of the device rod.

5. The display device of claim 4, wherein the second protrusion protrudes outward from the first protrusion in the first direction.

6. The display device of claim 4, wherein the pixel electrode is arranged along the first protrusion and the second protrusion.

7. The display device of claim 4, wherein the device rod comprises
a first conductivity-type semiconductor doped to a first polarity;
an active layer on the first conductivity-type semiconductor;
a second conductivity-type semiconductor on the active layer and doped to a second polarity opposite to the first polarity; and
an electrode material layer on the second conductivity-type semiconductor.

8. The display device of claim 7, wherein the at least one light-emitting element comprises a passivation layer around side surfaces of the first conductivity-type semiconductor, the active layer, the second conductivity-type semiconductor and the electrode material layer.

9. The display device of claim 2, wherein the first contact electrode is a high reflectance electrode.

10. The display device of claim 2, wherein the first contact electrode has a height from about 0.5 μm to about 3 μm.

11. The display device of claim 2, comprising one or more pixel connection holes penetrating through the organic layer in a sub-pixel area.

12. The display device of claim 11, wherein the pixel connection holes comprise a first pixel connection hole and a second pixel connection hole penetrating through the organic layer in the sub-pixel area,
wherein the at least one light-emitting element comprises a first light-emitting element and a second light-emitting element comprised in the sub-pixel area, and
wherein at least a part of the first pixel connection hole or a part of the second pixel connection hole overlaps the first light-emitting element or the second light-emitting element.

13. The display device of claim 12, wherein the pixel electrode covers a second part of the first pixel connection hole or a second part of the second pixel connection hole that does not overlap the first light-emitting element or the second light-emitting element.

14. The display device of claim 12, wherein a distance between the first pixel connection hole and the second pixel connection hole is greater than a difference between a width of the first light-emitting element and a width of the first pixel connection hole, and is smaller than a difference between a distance between the first light-emitting element and the second light-emitting element and a width of the first pixel connection hole.

15. A display device comprising:
a substrate;
a pixel electrode and a common electrode extending in a first direction on the substrate and spaced apart from each other in a second direction; and
at least one light-emitting element on the substrate and in a space between the pixel electrode and the common electrode, and
wherein the at least one light-emitting element comprises
a first contact electrode in contact with the pixel electrode on a side surface, and
a second contact electrode in contact with the common electrode at one end of the at least one light-emitting element.

16. The display device of claim 15, wherein the first contact electrode comprises a protrusion protruding outward from the second contact electrode in the first direction, and
wherein the pixel electrode is arranged along the protrusion.

17. The display device of claim 15, wherein the first contact electrode further comprises a first sub-contact electrode and a second sub-contact electrode, and
wherein the first sub-contact electrode comprises a first protrusion protruding outward from the second contact electrode in the first direction, and the second sub-contact electrode comprises a second protrusion protruding outward from the second contact electrode in the first direction.

18. The display device of claim 17, wherein the second protrusion protrudes outward from the first protrusion in the first direction.

19. The display device of claim 17, wherein the pixel electrode is arranged along the first protrusion and the second protrusion.

20. A method of fabricating a display device, the method comprising:
applying a circuit layer on a substrate;
bonding a light-emitting element on the circuit layer;
applying a material for forming a pixel electrode along an upper surface of the circuit layer and the light-emitting element;
patterning the pixel electrode by applying a photoresist, exposing it to light, and developing it;
applying a planarization layer on the pixel electrode; and
applying a common electrode on the planarization layer,
wherein the pixel electrode is in contact with a side surface of the light-emitting element.

21. The method of claim 20, wherein the bonding of the light-emitting element on the circuit layer comprises
bonding the light-emitting element comprising a first contact electrode and a device rod by applying the light-emitting element on the circuit layer, irradiating the light-emitting element with laser and pressing the light-emitting element, wherein the first contact electrode has a larger width than a width of the device rod in a first direction, and wherein the first direction is perpendicular to a stacking direction of the device rod.
